(19) United States
(12) Patent Application Publication
(10) Pub. No.: US 2016/0254164 A1
(43) Pub. Date: Sep. 1, 2016

(54) METHOD FOR STRIPPING MODIFIED RESIST, MODIFIED-RESIST STRIPPER USED THEREFOR, AND METHOD FOR MANUFACTURING SEMICONDUCTOR-SUBSTRATE PRODUCT

(71) Applicant: FUJIFILM Corporation, Tokyo (JP)

(72) Inventors: Yasuo SUGISHIMA, Haibara-gun (JP); Tetsuya KAMIMURA, Haibara-gun (JP); Atsushi MIZUTANI, Haibara-gun (JP)

(73) Assignee: FUJIFILM Corporation, Tokyo (JP)

(21) Appl. No.: 15/152,620

(22) Filed: May 12, 2016

Related U.S. Application Data
(63) Continuation of application No. PCT/JP2014/080222, filed on Nov. 14, 2014.

(30) Foreign Application Priority Data
Nov. 18, 2013 (JP) 2013-238343
Dec. 16, 2013 (JP) 2013-259532

(51) Int. Cl. H01L 21/311; G03F 7/42

(52) U.S. Cl. CPC H01L 21/31133; G03F 7/425; H01L 21/823857

(57) ABSTRACT

Provided is a stripping method for stripping a modified resist from a semiconductor substrate by applying an etching solution to the semiconductor substrate, in which the etching solution contains an alcohol compound and a quaternary ammonium hydroxide compound and the quaternary ammonium hydroxide compound is at least one of tetraethylammonium hydroxide and tetrabutylammonium hydroxide.

### CROSS-REFERENCE TO RELATED APPLICATIONS

This application is a Continuation of PCT International Application No. PCT/JP2014/080222 filed on Nov. 14, 2014, which claims priority under 35 U.S.C. §119 (a) to Japanese Patent Application No. 2013-238343 filed on Nov. 18, 2013, and to Japanese Patent Application No. 2013-259532 filed on Dec. 16, 2013. Each of the above applications is hereby expressly incorporated by reference, in its entirety, into the present application.

### BACKGROUND OF THE INVENTION

1. Field of the Invention

The present invention relates to a method for stripping a modified resist, a modified-resist stripper used therefor, and a method for manufacturing a semiconductor-substrate product.

2. Description of the Related Art

A process of manufacturing a semiconductor device includes various processes such as a lithography process, an etching process, and an ion implantation process. The process of manufacturing a semiconductor device includes a process of performing a treatment on an organic material after completion of each process or before moving to the next process. For example, a treatment of stripping and removing a resist remaining on a surface of a substrate is carried out.

As a conventional method for stripping an organic residue or a residual resist, a process of using a concentrated sulfuric acid hydrogen peroxide mixture (SPM) or an ammonia-peroxide mixture (APM) is used (see JP2005-268308A, JP2005-189660A, and JP2012-049391A). In this manner, a resist after a substrate is processed can be effectively stripped off. Meanwhile, according to this method, since the oxidizability of a liquid chemical is extremely strong even though the release properties of the resist are excellent, materials constituting the substrate may be damaged. When the recent situations of miniaturization of a semiconductor device and advancement of high integration are considered, it is desirable to avoid such damage even if the damage is minute. Further, the method of using an SPM or an APM is not necessarily satisfactory due to strong acidity or strong alkalinity of chemicals and occurrence of a rapid increase in the temperature.

As a stripper that does not use concentrated sulfuric acid or ammonia, a stripper that uses an amine, an organic solvent A, and a cosolvent is disclosed (see JP2013-500503A).

### SUMMARY OF THE INVENTION

In recent years, germanium (Ge) expected to have higher performance as a constituent element of a substrate than silicon (Si) has been attracting attention (see JP2001-119026A and JP2008-166809A). Germanium has low resistance to chemicals compared to silicon and this problem needs to be dealt with. Meanwhile, both of SPM described above and chemicals of JP2013-500503A described above cannot be preferably used due to severe corrosion of germanium (see the test results described below). Moreover, polysilicon which is applied to a gate electrode or the like is dissolved in the liquid chemical of JP2013-500503A described above and is damaged (see the test results described below). By considering such knowledge, development of an etching solution which has excellent release properties of a resist and excellent total performance including suppression of damage to respective members has been expected.

An object of the present invention is to provide a stripping method which suppresses or prevents damage to a polysilicon layer or a germanium layer when applied to a semiconductor substrate and is capable of suitably stripping a modified resist present on the top of the semiconductor substrate; a stripper used therefor; and a method for manufacturing a semiconductor-substrate product using the same.

The above-described problems are solved by using the following means.

[1] A stripping method comprising: applying an etching solution to a semiconductor substrate to strip a modified resist on the semiconductor substrate, in which the etching solution contains an alcohol compound and a quaternary ammonium hydroxide compound, and the quaternary ammonium hydroxide compound is at least one of tetraethylammonium hydroxide and tetrabutylammonium hydroxide.

[2] The stripping method according to [1], in which the semiconductor substrate has a germanium-containing layer or a polysilicon-containing layer.

[3] The stripping method according to [1] or [2] which is applied to the semiconductor substrate in a temperature range of 30° C. to 80° C.

[4] The stripping method according to [2] or [3], in which the etching rate of germanium or polysilicon is 200 Å/min or less.

[5] The stripping method according to any one of [1] to [4], in which the alcohol compound is a compound represented by the following Formula (O-1) or (O-2).

R^{O1}—(—O—R^{O2}—)ₙ—OH (O-1)

R^{O1} represents a hydrogen atom, an alkyl group having 1 to 12 carbon atoms, or an aryl group having 6 to 14 carbon atoms, R^{O2} represents a linear or branched alkylene chain having 1 to 12 carbon atoms, n represents an integer of 0 to 6, and when n represents 2 or greater, a plurality of R^{O2}'s may be different from each other, and in this case, when n represents 0, R^{O1} does not represent a hydrogen atom.

R^{O3}-L^{O1}-R^{O4}—OH (O-2)

R^{O3} represents a cyclic structural group which may have a substituent, L^{O1} represents a single bond, O, CO, NR^{N}, S, or a combination of these, R^{O4} represents a single bond, an alkylene group, an arylene group, or an aralkylene group, R^{N} represents a hydrogen atom, an alkyl group having 1 to 12 carbon atoms, an alkenyl group having 2 to 12 carbon atoms, or an aryl group having 6 to 14 carbon atoms, and when L^{O1} represents a linking group other than a single bond, R^{O4} does not represent a single bond.

[6] The stripping method according to any one of [1] to [5], in which a C Log P value of the alcohol compound is 0 or greater.

[7] The stripping method according to any one of [1] to [6], in which the alcohol compound is selected from 2-methyl-2,4-pentanediol, 3-methoxy-3-methyl-1-butanol, ethylene glycol, propylene glycol, benzyl alcohol, 2-phenylethanol, 2-phenoxyethanol, 2-ethylhexanol, and cyclohexanol.

[8] The stripping method according to any one of [1] to [7], in which the etching solution contains 10% by mass to 80% by mass of the alcohol compound.

[9] The stripping method according to any one of [1] to [8], in which the etching solution contains 20% by mass or less of the quaternary ammonium hydroxide compound.

[10] The stripping method according to any one of [1] to [9], in which the etching solution further contains 1% by mass to 50% by mass of water.

[11] The stripping method according to any one of [1] to [10], in which the etching solution further contains 1% by mass to 60% by mass of an organic amine compound.

[12] The stripping method according to any one of [2] to [11], in which the etching solution includes an anticorrosive component of the germanium-containing layer.

[13] The stripping method according to [12], in which the anticorrosive component of the germanium-containing layer is formed of a compound represented by any of the following Formulae (1) to (6), (10), and (11) or a compound having a repeating unit represented by any of the following Formulae (7) to (9).

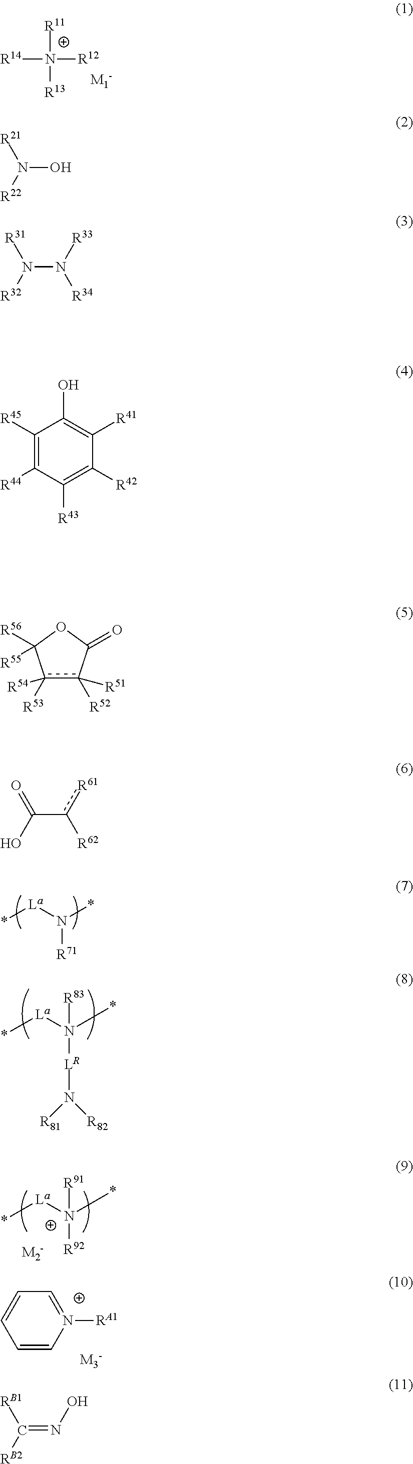

R¹¹ to R¹⁴, R²¹, R²², R³¹ to R³⁴, R⁴¹ to R⁴⁵, R⁵¹ to R⁵⁶, R⁶¹, R⁶², R⁷¹, R⁸¹ to R⁸³, R⁹¹, R⁹², R^{A1}, R^{B1}, and R^{B2} each independently represent a group including a hydrogen atom, a carbon atom, an oxygen atom, a sulfur atom, or a nitrogen atom, L^{a} represents a linking group, M₁⁻, M₂⁻, and M₃⁻ represent a counter anion, the broken line in Formula (5) represents any of a single bond and a double bond, and in the case where the broken line represents a double bond, R⁵² and R⁵⁴ are not present, the broken line in Formula (6) means that R⁶¹ represents an oxygen atom or a sulfur atom so that the oxygen atom or the sulfur atom may constitute a carbonyl group or a thiocarbonyl group together with a carbon atom to which the oxygen atom or the sulfur atom is bonded, and L^{R} represents a single bond or a linking group.

[14] The stripping method according to any one of [2] to [13], in which the etching solution includes a silicon compound as an anticorrosive component of the polysilicon-containing layer.

[15] A method for manufacturing a semiconductor-substrate product including:
manufacturing a semiconductor-substrate product by performing processes of the stripping method according to any one of [1] to [14].

[16] A stripper which removes a modified resist from a semiconductor substrate, comprising: an alcohol compound; and a quaternary ammonium hydroxide compound, in which the quaternary ammonium hydroxide compound is at least one of tetraethylammonium hydroxide and tetrabutylammonium hydroxide.

[17] The stripper according to [16], in which the semiconductor substrate has a germanium-containing layer or a polysilicon-containing layer.

[18] The stripper according to [16] or [17], containing 10% by mass to 80% by mass of the alcohol compound.

[19] The stripper according to any one of [16] to [18], containing 20% by mass or less of the quaternary ammonium hydroxide compound.

[20] The stripper according to any one of [16] to [19], further containing 1% by mass to 50% by mass of water.

[21] The stripper according to any one of [16] to [20], further containing 1% by mass to 60% by mass of an organic amine compound.

[22] The stripper according to any one of [16] to [21], further containing 0.01% by mass to 30% by mass of a silicon compound.

According to the present invention, it is possible to suitably strip a modified resist present on the top of a semiconductor-substrate while suppressing or preventing damage to a polysilicon layer or a germanium layer when a striper is applied to the semiconductor substrate. Further, according to the present invention, when the above-described stripper having excellent production suitability is applied, it is possible to provide a semiconductor-substrate product such as a complementary metal-oxide semiconductor (CMOS) with excellent product quality.

The above-described and other characteristics and advantages of the present invention will become evident from the description below and the accompanying drawings.

### BRIEF DESCRIPTION OF THE DRAWINGS

FIGS. 1A to 1D are process explanatory sectional views schematically illustrating a part of a process of manufacturing a semiconductor-substrate product according to an embodiment of the present invention.

FIG. 2 is a device configuration view illustrating a part of a treatment device according to a preferred embodiment of the present invention.

FIG. 3 is a plan view schematically illustrating a movement locus line of a nozzle with respect to a semiconductor substrate according to an embodiment of the present invention.

### DESCRIPTION OF THE PREFERRED EMBODIMENTS

### Stripping Treatment

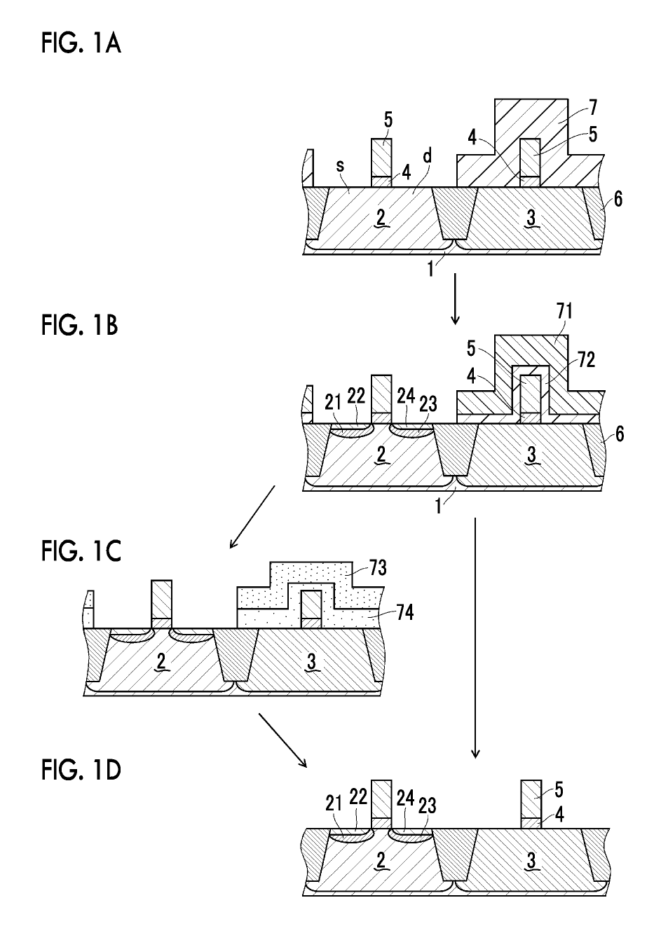

First, as a preferred embodiment of the present invention, a stripping treatment of an organic material will be described with reference to FIGS. 1A to 1D. FIGS. 1A to 1D show a process of the stripping treatment performed on a modified resist (modified organic material-containing layer) using an example of a process of manufacturing a CMOS. In FIG. 1A, a resist 7 is provided on a prepared semiconductor substrate. The semiconductor substrate here includes wells 2 and 3 including germanium, which are formed thereon, as a region in which a transistor is formed on a silicon Desired semiconductor properties (an n-type and a p-type) are provided for each well by ion-implanting arsenic, boron, or phosphorus. The semiconductor substrate of the present embodiment is in a state in which the surface of the well 2 side is exposed and the well 3 side is covered by the resist 7.

Next, in FIG. 1B, sources (21 and 22) and drains (23 and 24) are formed on the well 2. The sources and the drains may be formed according to a usual method, and processing carried out by performing an ion implantation process and a salicide process. First, the well 2 of the semiconductor substrate of FIG. 1A is coated with a suitable resist and specific conductivity type ions are implanted to an s region of FIG. 1A. In this manner, the regions constituting the sources are formed. Meanwhile, the regions constituting the drains are formed by changing the arrangement of resists and implanting opposite conductivity type ions to a d region of FIG. 1A. Thereafter, a layer of a metal such as titanium, nickel, or nickel platinum is formed so as to cover the surface of the substrate in the s region and the d region described above. Germanium silicide layers 22 and 24 are formed by annealing the metal layer. These layers function as an electrode unit exhibiting high conductivity in the sources and drains. By performing such a process, a substrate structure that includes sources and drains having a source base portion 21, the silicide layer 22, a drain base portion 23, and the silicide layer 24 is formed. In the present embodiment, an example in which a gate insulating film 4 and a gate electrode 5 are formed in advance is shown, but the present invention is not limited thereto. For example, a dummy gate is applied thereto so that a gate may be formed after the salicide process.

In the present invention, a layer including germanium is referred to as a germanium-containing layer (Ge-containing layer) in a wide sense, and the germanium-containing layer in the above-described example includes the wells 2 and 3, the source base portion 21, the source silicide portion 22, the drain base portion 23, and the drain silicide portion 24.

An example of the constituent material of the CMOS manufactured in the preferred embodiment of the present invention is described below. In this case, the present invention is not limitatively interpreted by the example below.
1: Silicon substrate: Si
4: Gate insulating film: HfO₂ (High-k)
5: Gate electrode: Al, W, polysilicon
21: Source base portion: SiGe, Ge
22: Source silicide portion: SiGe silicide, Ge silicide
23: Drain base portion: SiGe, Ge
24: Drain silicide portion: SiGe silicide, Ge silicide
Side wall (not illustrated): SiOCN, SiN, SiO₂ (low-k)
Cap (not illustrated): TiN

In the present embodiment, since the ion implantation process or the salicide process are performed for the purpose of forming the sources and the drains described above, the resist 7 applied onto the substrate before the processes are performed undergoes modification. In the example shown in the figure, a modified resist 71 is mainly affected by ion implantation and it is considered that the modified resist 71 is in a chemically changed state which is different from the state in which the resist 7 is provided on the substrate. When the resist undergoes such modification, the resist is carbonized and is unlikely to be stripped off unlike a typical resin. Particularly, in the present invention, it is preferable that the ion implantation is applied under the conditions of so-called high dose implantation strip (HDIS) because the effects thereof are remarkably exhibited. Typically, a case where the dosage of impurities to be ion-implanted exceeds 1×10¹⁴ cm⁻² is referred to as a high dosage, and the resist pattern is affected by ion impact and carbonized so that the surface of the resist pattern is significantly cured. Particularly the resist pattern on which a cured film is formed is unlikely to be removed. According to the preferred embodiment of the present invention, even such a modified resist can be suitably handled.

FIG. 1D illustrates the above-described modified resist 71 and an unmodified resist 72 which are stripped and removed by a stripper described below. According to the stripper of the preferred embodiment of the present invention, it is possible to excellently strip a resist, in which damage to the surface of the wells 2 and 3 including germanium is suppressed. Particularly, an unsaturated bond (a double bond and a triple bond) is generated in a modified product of a resist in HDIS and thus it is preferable that moderate hydrophobicity is provided for a stripper so that the unsaturated bond is dissolved and removed. From this viewpoint, as a component to be contained, it is preferable to apply a compound having a suitable number of carbon atoms.

FIG. 1C illustrates an example of a treatment in which plasma ashing is combined with a stripper according to another embodiment of the present invention. In this example, the substrate on which the resist of FIG. 1B is provided is irradiated with plasma and the above-described modified resist 71 is mainly removed. The modified resist 71 is unlikely to be stripped using a stripper in some cases. In such a case, a treatment in which plasma ashing is combined with the stripper is effective as in the present example. Meanwhile, a plasma-modified resist 73 remaining because of this treatment and a plasma-unmodified resist 74 begin to have stripping difficulty, which is different from the description above, due to the state of modification thereof. For example, the portion of the modified resist 73 is turned into ashes because of the plasma treatment and is unlikely to be dissolved in some cases. According to the stripper of the preferred embodiment of the present invention, it is possible to desirably strip and remove such a plasma-modified resist.

The above-described plasma ashing may be carried out according to a usual method, and oxygen plasma ashing or the like can be applied. However, the material of the substrate is occasionally damaged by the oxygen plasma. For this reason, an improved process described below may be applied in order to avoid the material from being damaged. JP2010-098279A suggests that a gas including hydrogen, a weak oxidant, and a fluorine-containing gas is introduced into a plasma source. Specifically, a plasma-activated gas including elemental hydrogen, a weak oxidant, and a fluorine-containing gas is allowed to flow in the semiconductor substrate together with an inert gas to react with the material of the semiconductor substrate. Examples of the weak oxidant include carbon dioxide, carbon monoxide, nitrogen dioxide, nitrogen oxide, water, hydrogen peroxide, and a combination of these. Examples of the fluorine-containing gas include carbon tetrafluoride, C₂F₆, C₃F₈, hydrofluorocarbon, CHF₃, CH₂F₂, elemental fluorine, nitrogen trifluoride, sulfur hexafluoride, and a combination of these. Examples of the inert gas include argon, helium, nitrogen, and a combination of these.

The gas to be introduced into a plasma source may or may not be mixed with another gas and can be introduced in an amount of 0.1% by volume to 10% by volume. The inert gas is introduced at a volume flow of approximately two times the volume flow of the active gas. The plasma is generated as a remote plasma using an RF output of 300 W to 10 KW. The temperature of the semiconductor substrate may be in a range of approximately 160° C. to 500° C. when a gas is brought into contact with the semiconductor substrate. The process pressure can be set to be in a range of 300 mTorr to 2 Torr.

In the present specification, the term semiconductor substrate is used to describe the entire substrate structure including not only a wafer but also a substrate for which a circuit structure is provided. A semiconductor substrate member indicates a member constituting the semiconductor substrate defined as above and may be formed of one material or a plurality of materials. Further, a processed semiconductor substrate is distinguished and referred to as a semiconductor-substrate product in some cases, and when further distinguished, if necessary, a chip taken out by adding a process to the semiconductor substrate and carrying out dicing thereon and a processed product thereof are referred to as a semiconductor device. In other words, a semiconductor device belongs to a semiconductor-substrate product in a wide sense. The direction of the semiconductor substrate is not particularly limited, but, in the present specification, the gate side is set to the upward direction and the silicon substrate side is set to the downward direction for the convenience of description. Moreover, in the accompanying drawings, the structure of the semiconductor substrate or the member thereof is simplified for illustration and may be interpreted as a necessary form if necessary.

(Stripper)

The stripper according to the preferred embodiment of the present invention contains an alcohol compound and a quaternary ammonium hydroxide compound as liquid chemical components. Hereinafter, the respective components will be described.

<Alcohol Compound>

The alcohol compound includes a wide range of compounds that have carbon and hydrogen in a molecule and one or more hydroxy groups. The number of carbon atoms of the alcohol compound is preferably 1 or greater, more preferably 2 or greater, still more preferably 3 or greater, even still more preferably 4 or greater, even still more preferably 5 or greater, and particularly preferably 6 or greater. The upper limit of the carbon atoms is preferably 24 or less, more preferably 12 or less, and particularly preferably 8 or less. Examples thereof include an ether group-non-containing alcohol compound such as methyl alcohol, ethyl alcohol, 1-propyl alcohol, 2-propyl alcohol, 2-butanol, ethyl glycol, propylene glycol, glycerin, 1,6-hexanediol, cyclohexanediol, sorbitol, xylitol, 2-methyl-2,4-pentanediol, 1,3-butanediol, 1,4-butanediol, cyclohexanol, 2-ethylhexanol, benzyl alcohol, or 2-phenylethanol; and an ether group-containing alcohol compound such as alkylene glycol alkyl ether (for example, ethylene glycol monomethyl ether, ethylene glycol monobutyl ether, diethylene glycol, dipropylene glycol, propylene glycol monomethyl ether, diethylene glycol monomethyl ether, triethylene glycol, polyethylene glycol, propylene glycol monomethyl ether, dipropylene glycol monomethyl ether, tripropylene glycol monomethyl ether, diethylene glycol monobutyl ether, or diethylene glycol monobutyl ether), 2-phenoxyethanol, or 3-methoxy-3-methyl-1-butanol. Among these, benzyl alcohol and 2-methyl-2,4-pentanediol are particularly preferable.

It is preferable that the alcohol compound is a compound represented by the following Formula (O-1).

R^{O1}—(—O—R^{O2}—)ₙ—OH (O-1)

R^{O1}

R^{O1} represents a hydrogen atom, an alkyl group having 1 to 12 carbon atoms (the number of carbon atoms is preferably in a range of 1 to 6 and more preferably in a range of 1 to 3), or an aryl group having 6 to 14 carbon atoms (the number of carbon atoms is preferably in a range of 6 to 10).

R^{O2}

R^{O2} represents a linear or branched alkylene chain having 1 to 12 carbon atoms. When a plurality of R^{O2}'s are present, R^{O2}'s may be different from each other. The number of carbon atoms of R^{O2} is preferably in a range of 2 to 10, more preferably in a range of 2 to 6, and still more preferably in a range of 2 to 4. Alternatively, when adsorptivity to a specific metal or the surface of a metal compound is considered, it is preferable that R^{O2} represents an alkylene chain having 3 to 12 carbon atoms, and the number of carbon atoms thereof is preferably in a range of 3 to 10, more preferably in a range of 3 to 6, and still more preferably 3 or 4. Particularly, a structure in which at least one carbon atom is interposed between OH groups is preferable.

n

n represents an integer of 0 to 6. When n represents an integer of 2 or greater, a plurality of R^{O2}'s may be different from each other. Here, when n represents an integer of 0, R^{O1} does not represent a hydrogen atom.

It is preferable that a compound represented by Formula (O-1) is represented by the following Formula (X).

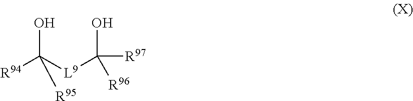

In the formula, R⁹⁴ to R⁹⁷ each independently represent a hydrogen atom, an alkyl group (the number of carbon atoms is preferably in a range of 1 to 12, more preferably in a range of 1 to 6, and particularly preferably in a range of 1 to 3), an alkenyl group (the number of carbon atoms is preferably in a range of 2 to 12 and more preferably in a range of 2 to 6), an alkynyl group (the number of carbon atoms is preferably in a range of 2 to 12 and more preferably in a range of 2 to 6), an aryl group (the number of carbon atoms is preferably in a range of 6 to 22 and more preferably in a range of 6 to 14), an acyl group (the number of carbon atoms is preferably in a range of 2 to 12 and more preferably in a range of 2 to 6), or an aralkyl group (the number of carbon atoms is preferably in a range of 7 to 23 and more preferably in a range of 7 to 15). R⁹⁴ to R⁹⁷ may further have a substituent T such as a hydroxy group.

L⁹ represents an alkylene group, and an alkylene group having 1 to 12 carbon atoms is preferable, an alkylene group having 1 to 8 carbon atoms is more preferable, an alkylene group having 1 to 6 carbon atoms is still more preferable, and an alkylene group having 1 to 4 carbon atoms is particularly preferable. It is preferable that L⁹ does not have a hydroxyl group.

It is preferable that the alcohol compound is a compound represented by the following Formula (O-2).

R^{O3}-L^{O1}-R^{O4}—OH (O-2)

R^{O3} represents a cyclic structural group which may have a substituent. The cyclic structural group may be a hydrocarbon aromatic group, a heterocyclic aromatic group, a cyclic aliphatic group, or a cyclic heteroaliphatic group. Examples of the hydrocarbon aromatic group include an aryl group having 6 to 14 carbon atoms (an aryl group having 6 to 10 carbon atoms is preferable and a phenyl group is more preferable). Examples of the cyclic aliphatic group include a cyclic alkyl group having 6 to 14 carbon atoms (a cyclic alkyl group having 6 to 10 carbon atoms is preferable and a cyclohexyl group is more preferable). Examples of a heterocycle are the same as those of a substituent T described below. Further, examples of a substituent which may be included in a cyclic structural group are the same as those of the substituent T described below.

L^{O1} represents a single bond, O, CO, NR^{N}, S, or a combination of these. Among these, a single bond, CO, or O is preferable and a single bond or O is more preferable.

R^{O4} represents a single bond, an alkylene group (the number of carbon atoms is preferably in a range of 1 to 12, more preferably in a range of 1 to 6, and particularly preferably in a range of 1 to 3), an arylene group (the number of carbon atoms is preferably in a range of 6 to 14 and more preferably in a range of 6 to 10), or an aralkyl group (the number of carbon atoms is preferably in a range of 7 to 15 and more preferably in a range of 7 to 11). R^{N} has the same definition as that described below. When L^{O1} represents a linking group other than a single bond, le does not represent a single bond.

The C Log P value of the alcohol compound is preferably −0.5 or greater, more preferably 0 or greater, still more preferably 0.1 or greater, even still more preferably 0.2 or greater, even still more preferably 0.3 or greater, and particularly preferably 0.5 or greater. The upper limit thereof is not particularly limited, but is preferably 5 or less, more preferably 3 or less, and still more preferably 2 or less. Examples of the C Log P values of several compounds are shown below.

| | |
|---|---|
| 2-methyl-2,4-pentanediol | 0.17 |
| Benzyl alcohol | 1.06 |
| 2-phenylethanol | 1.56 |
| 2-phenoxyethanol | 1.19 |
| 3-methoxy-3-methyl-1-butanol | 0.63 |
| 2-ethylhexanol | 2.82 |
| Cyclohexanol | 1.49 |
| Ethylene glycol | −1.36 |
| Propylene glycol | −0.92 |

An octanol-water partition coefficient (log P value) can be typically measured according to a flask infiltration method described in JIS Japanese Industrial Standards Z7260-107 (2000). Further, the octanol-water partition coefficient (log P value) can be estimated by a calculating chemical method or an empirical method instead of actual measurement. It is known that a Crippen's fragmentation method (J. Chem. Inf. Comput. Sci., 27, 21 (1987)), a Viswanadhan's fragmentation method (J. Chem. Inf. Comput. Sci., 29, 163 (1989)), Broto's fragmentation method (Eur. J. Med. Chem.—Chim. Theor., 19, 71 (1984)), or the like is used as the calculation method thereof. In the present invention, the Crippen's fragmentation method (J. Chem. Inf. Comput. Sci., 27, 21 (1987)) is used.

The C log P value is obtained by calculating a common logarithm log P of a partition coefficient P to 1-octanol and water. A known method or known software can be used for calculating the C log P value, but, unless otherwise noted, a system from Daylight Chemical Information System, Inc. and a C log P program incorporated in PCModels are used in the present invention.

Specific examples of the alcohol compound include methanol, ethanol, 1-propanol, 2-propanol, 2-butanol, 2-ethylhexanol, ethylene glycol, propylene glycol, glycerin, 1,6-hexanediol, cyclohexanediol, sorbitol, xylitol, polyethylene glycol (such as diethylene glycol or triethylene glycol), polypropylene glycol (such as dipropylene glycol or tripropylene glycol), 2-methyl-2,4-pentanediol, 3-methoxy-3-methyl-1-butanol, hexylene glycol, 1,3-butanediol, and 1,4-butanediol. Further, examples of alkylene glycol monoalkyl ether include ethylene glycol monomethyl ether, ethylene glycol monobutyl ether, propylene glycol monomethyl ether, diethylene glycol monomethyl ether, triethylene glycol monomethyl ether, tetraethylene glycol monomethyl ether, dipropylene glycol monomethyl ether, tripropylene glycol monomethyl ether, diethylene glycol monobutyl ether, and dipropylene glycol monobutyl ether. Examples of alcohol having a cyclic group include benzyl alcohol, 2-phenylethanol, 2-phenoxyethanol, and cyclohexanol.

The content of the alcohol compound in the stripper is preferably 10% by mass or greater, more preferably 20% by mass or greater, and still more preferably 30% by mass or greater. The upper limit thereof is particularly preferably 90% by mass or less, more preferably 80% by mass or less, and still more preferably 70% by mass or less. When the content thereof is in the above-described range, desirable anticorrosive effects and release properties of the modified resist can be obtained, which is preferable.

The above-described alcohol compound may be used alone or in combination of two or more kinds thereof.

(Quaternary Ammonium Hydroxide Compound)

The quaternary ammonium hydroxide compound of the present invention includes at least one of tetraethyl ammonium hydroxide (TEAH) and tetrabutylammonium hydroxide (TBAH). The quaternary ammonium hydroxide compound may have other quaternary ammonium hydroxide. Examples of quaternary ammonium hydroxide which can be used in combination include tetramethyl ammonium hydroxide (TMAH) and tetrapropyl ammonium hydroxide (TPAH). Further, examples of quaternary ammonium hydroxide include trimethyl hydroxyl ethyl ammonium hydroxide (choline), methyl tri(hydroxyethyl)ammonium hydroxide, tetra(hydroxyethyl)ammonium hydroxide, and benzyl trimethyl ammonium hydroxide (BTMAH).

The content of the quaternary ammonium hydroxide compound in the stripper is preferably greater than 0% by mass, more preferably 0.1% by mass or greater, and still more preferably 0.5% by mass or greater. The upper limit thereof is particularly preferably 40% by mass or less, more preferably 20% by mass or less, and still more preferably 15% by mass or less. When the content thereof is in the above-described range, desirable anticorrosive effects and release properties of the modified resist can be obtained, which is preferable.

The quaternary ammonium hydroxide compound may be used alone or in combination of two or more kinds thereof. Among the quaternary ammonium hydroxide compounds, when a quaternary ammonium hydroxide compound having a hydrophobic counter cation is used, desirable anticorrosive effects (particularly polysilicon) are exhibited. It is considered that desirable anticorrosive effects are exhibited because the counter cation is adsorbed to polysilicon and the surface of a metal so that solvation is suppressed.

(Water)

Water to be applied to the stripper of the present invention is not particularly limited, but an aqueous medium including a dissolved component may be used within the range not impairing the effects of the present invention. Alternatively, the aqueous medium may include a trace amount of inevitable mixed components. As the water, water subjected to a purification treatment such as distilled water, ion-exchange water, or ultrapure water is preferable and ultrapure water used for manufacturing a semiconductor is particularly preferable. The amount of water in the stripper is preferably 1% by mass or greater, more preferably 3% by mass or greater, still more preferably 5% by mass or greater, even still more preferably 8% by mass or greater, even still more preferably 12% by mass or greater, and particularly preferably 15% by mass or greater. The upper limit thereof is preferably 50% by mass or less, more preferably 35% by mass or less, and particularly preferably 25% by mass or less. When the amount thereof is in the above-described range, desirable anticorrosive effects and release properties of the modified resist can be obtained, which is preferable.

(Organic Amine Compound)

Organic amine compounds include a compound including a primary amine, a secondary amine, and a tertiary amine. A carbamoyl group or a salt thereof is to be included therein. Meanwhile, a quaternary ammonium compound is not included therein. Here, it is preferable that an organic group of the organic amine compound is a hydrocarbon group, and examples thereof include an alkane residue (typically an alkyl group, but the alkane residue may be a divalent or higher valent group, the same applies to other residues), an alkene residue, an aryl residue, or a combination of these. The number of carbon atoms of the organic group is 1 or greater, and the upper limit thereof is practically 16 or less. It is preferable that the organic amine compound is an amino alcohol compound (the number of carbon atoms is preferably in a range of 1 to 16, more preferably in a range of 1 to 12, and still more preferably in a range of 1 to 6) having an amino group and a hydroxy group in a molecule.

As the organic amine compound, a compound represented by any of the following Formulae (P-1) to (P-3) is exemplified.

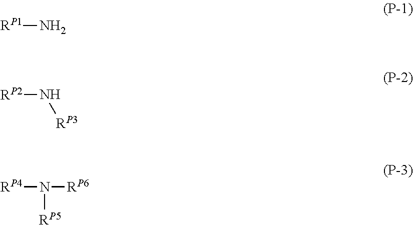

In the formula, R^{P1} to R^{P6} each independently represent an alkyl group (the number of carbon atoms is preferably in a range of 1 to 12, more preferably in a range of 1 to 6, and particularly preferably in a range of 1 to 3), an alkenyl group (the number of carbon atoms is preferably in a range of 2 to 12, more preferably in a range of 2 to 6, and particularly preferably 2 or 3), an alkynyl group (the number of carbon atoms is preferably in a range of 2 to 12, more preferably in a range of 2 to 6, and particularly preferably 2 or 3), and an aryl group (the number of carbon atoms is preferably in a range of 6 to 14 and more preferably in a range of 6 to 10). In this case, at least one of R^{P1} to R^{P6} in a molecule includes a hydroxy group.

The alkyl group, the alkenyl group, and the aryl group described above may further have a substituent, and examples of an optional substituent are the same as those of a substituent T described below. Among the examples, a hydroxy group, a carboxyl group, a sulfanyl group, an acyl group, and an alkoxy group, defined in the examples of the substituent T, are preferable.

In the present invention, it is particularly preferable that a primary amine of Formula (P-1) is used.

When R^{P1} to R^{P6} include an alkyl group, an alkenyl group, and an alkynyl group, a hetero linking group (Ly: S, O, CO, or NRN) may be interposed. When an alkyl group or an alkenyl group having a hydroxy group has a hetero linking group, a group of Formula P-4 is exemplified as a specific structure thereof

OH—R^{P7}-Ly-R^{P8}-* (P-4)

R^{P7} and R^{PS} represent an alkylene group having 1 to 12 carbon atoms (the number of carbon atoms is preferably in a range of 1 to 6 and more preferably in a range of 1 to 3) or an alkenylene group having 2 to 12 carbon atoms (the number of carbon atoms is preferably in a range of 2 to 6 and more preferably 2 or 3). The symbol “*” represents a binding site.

It is preferable that the organic amine compound is selected from monoethanolamine (2-aminoethanol) (MEA), diethanolamine (DEA), N-methylethanol amine (NMEA), N,N-dimethylethanolamine (DMMEA), N-methyldiethanolamine (DEMEA), aminoethylethanolamine (AEMEA), N,N-dimethylaminoethyl ethanolamine (DMAEMEA), aminoethoxy ethanol (AEE), N,N-dimethylamino ethoxy ethanol (DMAEE), and propanolamine (MPA).

The content of the organic amine compound in the stripper is preferably 1% by mass or greater, more preferably 2% by mass or greater, and still more preferably 5% by mass or greater. The upper limit thereof is preferably 60% by mass or less, more preferably 50% by mass or less, still more preferably 45% by mass or less, even still more preferably 35% by mass or less, even still more preferably 30% by mass or less, and particularly preferably 25% by mass or less. When the content thereof is in the above-described range, desirable anticorrosive effects and release properties of the organic material-containing layer can be obtained, which is preferable.

In terms of the relationship between the organic amine compound and the alcohol compound, the content of the organic amine compound is preferably 5 parts by mass or greater, more preferably 10 parts by mass or greater, and particularly preferably 20 parts by mass or greater with respect to 100 parts by mass of the alcohol compound. The upper limit thereof is preferably 120 parts by mass or less, more preferably 100 parts by mass or less, and particularly preferably 80 parts by mass or less. When the concentration of the organic amine compound is in the above-described range, desirable anticorrosive effects and release properties of the modified resist can be obtained, which is preferable.

The above-described organic amine compound may be used alone or in combination of two or more kinds thereof

(Fluorine-Containing Compound)

The stripper of the present invention may further contain a fluorine-containing compound. The fluorine-containing compound is not particularly limited as long as fluorine is included in a molecule, and a compound dissociating in water to release fluorine ions is preferable. Specific examples thereof include hydrofluoric acid (fluoric acid), ammonium fluoride, tetramethylammonium fluoride, tetrafluoroboric acid, hexafluorophosphoric acid, hexafluorosilicic acid, ammonium tetrafluoroborate, ammonium hexafluorophosphate, and ammonium hexafluorosilicate. As a counter ion, a cation other than ammonium, for example, tetramethylammonium may be used.

The concentration of the fluorine-containing compound is preferably 0.001% by mass or greater, more preferably 0.01% by mass or greater, still more preferably 0.02% by mass or greater, and particularly preferably 0.03% by mass or greater based on the total mass of the etching solution of the present embodiment. The upper limit thereof is preferably in a range of 10% by mass or less, more preferably 5% by mass or less, and still more preferably 2% by mass or less.

Moreover, the fluorine-containing compound may be used alone or in combination of two or more kinds thereof

(Anticorrosive Component)

When a treatment of a substrate including a germanium-containing layer is performed, it is preferable that the stripper of the present invention contains an anticorrosive component. It is preferable that the anticorrosive component is a nitrogen-containing organic compound or an oxygen-containing organic compound.

Examples of the nitrogen-containing organic compound include compounds having an amino group (NR^{N}₂), an imino group (NR^{N}), an ammonium group (NR^{M}₄⁺), a pyridinium group (C₅NR^{M+}), and an imidazolidinium group (C₃N₂R^{M}₂⁺). Here, R^{N} represents a hydrogen atom, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10). R^{M} represents an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10).

Examples of the oxygen-containing organic compound include compounds having a hydroxy group (OH), a carboxyl group (COOH), a carbonyl group (CO), an ether group (O), and a group related to a combination of these.

It is preferable that the above-described anticorrosive is a compound represented by any of the following Formulae (1) to (6), (10), and (11) or a compound having a repeating unit represented by any of the following Formula (7) to (9).

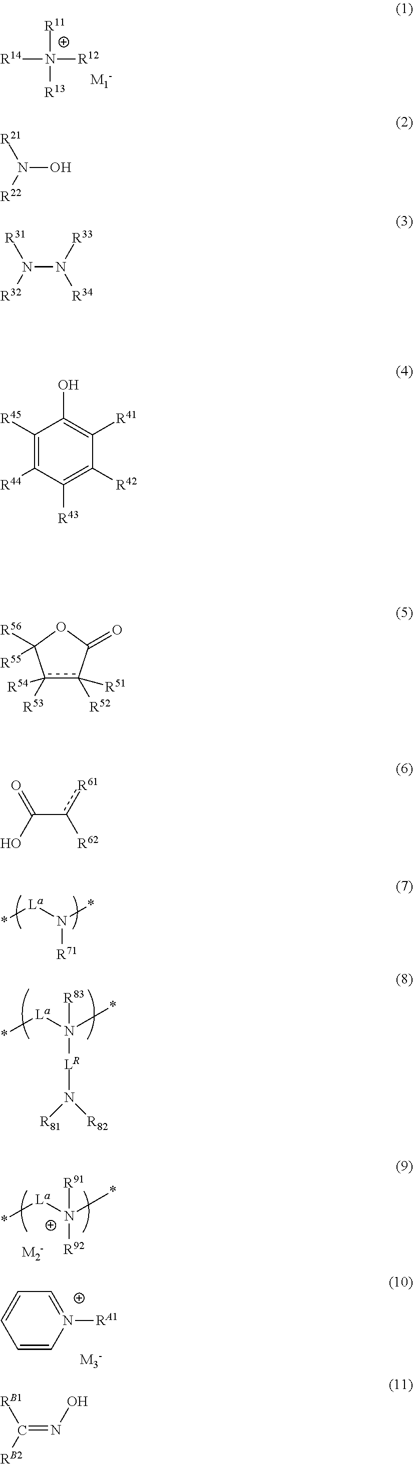

R¹¹ to R¹⁴, R²¹, R²², R³¹ to R³⁴, R⁴¹ to R⁴⁵, R⁵¹ to R⁵⁶, R⁶¹, R⁶², R⁷¹, R⁸¹ to R⁸³, R⁹¹, R⁹², R^{A1}, R^{B1}, and R^{B2} each independently represent a group including a hydrogen atom, a carbon atom, an oxygen atom, a sulfur atom, or a nitrogen atom.

L^{a} represents a linking group. Preferred examples thereof are the same as those defined in the following Formulae (a-1) to (a-8).

M₁⁻, M₂⁻, and M₃⁻ represent a counter anion. Examples thereof include a hydroxide ion and a halogen anion.

The broken line in Formula (5) represents any of a single bond and a double bond. When the broken line represents a double bond, R⁵² and R⁵⁴ are not present.

The broken line in Formula (6) means that R⁶¹ represents an oxygen atom or a sulfur atom so that the oxygen atom or the sulfur atom may constitute a carbonyl group (C═O) or a thiocarbonyl group (C═S) together with a carbon atom to which the oxygen atom or the sulfur atom is bonded.

L^{R} represents a single bond or a linking group. Preferred examples thereof are the same as those of L^{b} described below.

Adjacent substituents may be linked to each other to form a ring. A ring to be formed is not particularly limited, but a 4- to 6-membered ring is preferable and a 4- to 6-membered heteroaliphatic ring or hydrocarbon aliphatic ring is more preferable. Examples of a group that forms a ring include R¹¹ to R¹⁴, R²¹, R²², R³¹, R³², R³³, R³⁴, R⁴¹ to R⁴⁵, R⁵¹ to R⁵⁶, R⁶¹, R⁶², R⁸¹, R⁸², R^{B1}, and R^{B2}.

Formula (1)

It is preferable that R¹¹ to R¹⁴ each independently represent an alkyl group having 1 to 24 carbon atoms (the number of carbon atoms is preferably in a range of 1 to 20, more preferably in a range of 1 to 16, and still more preferably in a range of 1 to 8), an alkenyl group having 2 to 24 carbon atoms (the number of carbon atoms is preferably in a range of 2 to 20, more preferably in a range of 2 to 16, and still more preferably in a range 2 to 8), or an aryl group having 6 to 14 carbon atoms (the number of carbon atoms is preferably 6 to 10). At this time, it is preferable that at least one of R¹¹ to R¹⁴ has 2 or more carbon atoms. When a compound of Formula (1) is tetraalkyl ammonium hydroxide, examples thereof include tetramethyl ammonium hydroxide (TMAH), but, as described above, tetraalkyl ammonium hydroxide having 5 or more carbon atoms, which has more carbon atoms that that of TMAH is preferable, tetraalkyl ammonium hydroxide having 8 or more carbon atoms is more preferable, tetraalkyl ammonium hydroxide having 12 or more carbon atoms is still more preferable, and tetraalkyl ammonium hydroxide having 16 or more carbon atoms is particularly preferable. This is because tetraalkyl ammonium hydroxide is preferably hydrophobic in the relationship between tetraalkyl ammonium hydroxide and components included in an organic material-containing layer such as a modified resist, a residue, and the like. Moreover, in a developer described below, tetramethyl ammonium hydroxide is also used as an alkali component and, in this case, an anticorrosive component can be defined as a component other than tetramethyl ammonium hydroxide.

The alkyl group, the alkenyl group, and the aryl group described above may further have a substituent and examples of an optional substituent are the same as those of the substituent T described below. Among the examples, a hydroxy group, a carboxyl group, a sulfanyl group, an acyl group, an alkoxy group, and an amino group, defined in the examples of the substituent T, are preferable. The same applies to the following Formulae (2) to (11).

Formula (2)

It is preferable that R²¹ and R²² each independently represent a hydrogen atom, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), an aryl group having 6 to 14 carbon atoms (the number of carbon atoms is preferably 6 to 10), an acyl group having 1 to 12 carbon atoms (the number of carbon atoms is preferably in a range of 1 to 6 and more preferably in a range of 1 to 3), an alkoxy group having 1 to 12 carbon atoms (the number of carbon atoms is preferably in a range of 1 to 6 and more preferably in a range of 1 to 3), an amino carbonyl group (NR^{N}₂CO), a hydrazino group (NR^{N}—NR^{N}₂), a hydradinocarbonyl group (CO—NR^{N}—NR^{N}₂), or C(NR^{N})NR^{N}₂, R²¹ and R²² may be linked to each other to form a ring as described above. Among the structures of the ring, it is preferable to employ a structure represented by the following Formula (2-1) when a ring is formed.

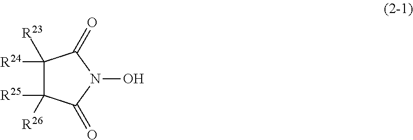

R²³ to R²⁶ each independently represent a hydrogen atom or a substituent. Examples of the substituent include an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), and an aryl group having 6 to 14 carbon atoms (the number of carbon atoms is preferably in a range of 6 to 10). R²³ to R²⁶ may be linked to each other and form a ring. For example, it is preferable that a benzene ring is formed to have a phthalimide structure.

Formula (3)

It is preferable that R³¹ to R³⁴ have the same definitions as those for R²¹ and R²² (a hydrogen atom or a specific substituent). It is preferable that Formula (3) is represented by the following Formula (3-1).

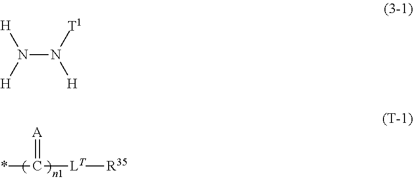

In Formula (3-1), a substituent T¹ is a substituent of Formula (T1).

In Formula (T1), A represents an oxygen atom (O), a sulfur atom (S), or an imino group (NR^{N}). n1 represents 0 or 1. L^{T} represents a single bond, an alkylene group having 1 to 12 carbon atoms (the number of carbon atoms is preferably in a range of 1 to 6 and more preferably in a range of 1 to 3), an alkenylene group (the number of carbon atoms is preferably in a range of 2 to 6 and more preferably 2 or 3), or an alkynylene group (the number of carbon atoms is preferably in a range of 2 to 6 and more preferably 2 or 3).

R³⁵ represents a hydroxy group, a carboxyl group, or an ester thereof [alkoxycarbonyl group] (the number of carbon atoms of the ester is preferably in a range of 1 to 6), a sulfanyl group, an alkyl group (the number of carbon atoms is in a range of 1 to 24, more preferably in a range of 1 to 12, and particularly preferably in a range of 1 to 6), an alkenyl group (the number of carbon atoms is in a range of 2 to 24, more preferably in a range of 2 to 12, and particularly preferably in a range of 2 to 6), an alkynyl group (the number of carbon atoms is in a range of 2 to 24, more preferably in a range of 2 to 12, and particularly preferably in a range of 2 to 6), an aryl group (the number of carbon atoms is in a range of 6 to 24, more preferably in a range of 6 to 14, and particularly preferably in a range of 6 to 10), an alkoxy group (the number of carbon atoms is in a range of 1 to 24, more preferably in a range of 1 to 12, and particularly preferably in a range of 1 to 6), an acyl group (the number of carbon atoms is in a range of 1 to 24, more preferably in a range of 1 to 12, and particularly preferably in a range of 1 to 6), an amino group (NR^{N}₂), a hydrazino group (NR^{N}—NR^{N}₂), or a hydradinocarbonyl group (CO—NR^{N}—NR^{N}₂).

Formula (4)

It is preferable that R⁴¹ to R⁴⁵ each independently represent a hydrogen atom, a hydroxy group, a carboxyl group, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10). The carboxyl group may be an ester thereof [alkoxycarbonyl group] (the number of carbon atoms of the ester is preferably in a range of 2 to 6). It is preferable that at least one of R⁴¹ to R⁴⁵ represents a carboxyl group or an ester thereof. Further, it is preferable that at least one of R⁴¹ to R⁴⁵ represents a hydroxy group.

Formula (5)

It is preferable that R⁵¹ to R⁵⁶ each independently represent a hydrogen atom, a hydroxy group, a carboxyl group, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10). The carboxyl group may be an ester thereof [alkoxycarbonyl group] (the number of carbon atoms of the ester is preferably in a range of 2 to 6). It is preferable that Formula (5) is represented by the following Formula (5-1).

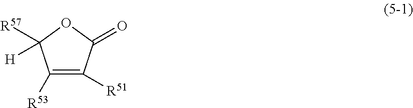

In Formula (5-1), it is preferable that R⁵⁷ represents an alkyl group (the number of carbon atoms is preferably in a range of 1 to 12, more preferably in a range of 1 to 6, and still more preferably in a range of 1 to 3) having a hydroxyl group. The hydroxyl group may be esterified. As an example of R⁵⁷, —CH(OH)—CH₂—O-T¹ is exemplified. T¹ has the same definition as that in Formula (3-1) above.

Formula (6)

It is preferable that R⁶¹ and R⁶² each independently represent a hydrogen atom, a hydroxyl group, a carboxyl group, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), an aryl group having 6 to 14 carbon atoms (the number of carbon atoms is preferably in a range of 6 to 10), or an oxygen atom forming a carbonyl group. It is preferable that Formula (6) is represented by the following Formula (6-1).

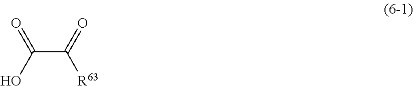

In Formula (6-1), it is preferable that R⁶³ represents a hydrogen atom, a hydroxy group, or an alkyl group (the number of carbon atoms is preferably in a range of 1 to 12, more preferably in a range of 1 to 6, and still more preferably in a range of 1 to 3) having a hydroxy group.

Formula (7)

It is preferable that R⁷¹ represents a hydrogen atom, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10).

Formula (8)

It is preferable that R⁸¹ and R⁸² represent a hydrogen atom, an alkyl group having 1 to 12 carbon atoms (the number of carbon atoms is preferably in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10). R⁸¹ and R⁸² may be bonded to each other or condensed to each other to form a ring.

It is preferable that R⁸³ represents a methyl group, an ethyl group, or a propyl group.

Formula (9)

It is preferable that R⁹¹ and R⁹² represent a hydrogen atom, an alkyl group having 1 to 12 carbon atoms (the number of carbon atoms is preferable in a range of 1 to 6 and more preferably in a range of 1 to 3), an alkenyl group having 2 to 12 carbon atoms (the number of carbon atoms is preferably in a range of 2 to 6 and more preferably 2 or 3), or an aryl group having 6 to 14 carbon atoms (the number of carbon atoms is preferably in a range of 6 to 10).

Formula (10)

It is preferable that R^{A1} represents an alkyl group having 1 to 24 carbon atoms (the number of carbon atoms is preferable in a range of 1 to 20 and more preferably in a range of 1 to 16), an alkenyl group having 2 to 24 carbon atoms (the number of carbon atoms is preferably in a range of 2 to 20 and more preferably in a range of 2 to 16), or an aryl group having 6 to 14 carbon atoms (the number of carbon atoms is preferably in a range of 6 to 10). The pyridine ring in the formula may have a substituent.

Formula (11)

It is preferable that R^{B1} and R^{B2} each independently represent an alkyl group having 1 to 12 carbon atoms (the number of carbon atoms is preferable in a range of 1 to 6 and more preferably in a range of 1 to 3), an alkenyl group having 2 to 12 carbon atoms (the number of carbon atoms is preferably in a range of 2 to 6 and more preferably 2 or 3), an aryl group having 6 to 14 carbon atoms (the number of carbon atoms is preferably in a range of 6 to 10) or an amino group (NR^{N}₂).

The compounds represented by Formulae (7) to (9) may be formed of only repeating units in the formulae or may have other repeating units.

It is preferable that a compound represented by any of Formulae (7) to (9) has a repeating unit selected from the following Formulae (a-1) to (a-8).

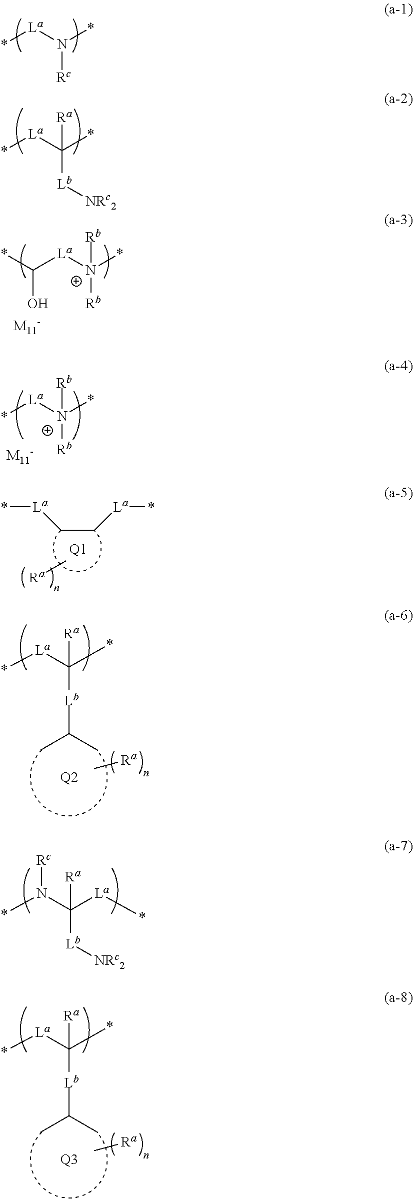

R^{a}

R^{a} represents a hydrogen atom, an alkyl group (the number of carbon atoms is preferably 1 to 12, more preferably in the range of 1 to 6, and particularly preferably in the range of 1 to 3), an alkenyl group (the number of carbon atoms is preferably 2 to 12 and more preferably in the range of 2 to 6), an aryl group (the number of carbon atoms is preferably 6 to 22 and more preferably in the range of 6 to 14), or a heterocyclic group (the number of carbon atoms is preferably 2 to 12 and more preferably in the range of 2 to 6). Among these, it is preferable that R^{a} represents a hydrogen atom or a methyl group. In addition, an alkyl group in the present specification includes an aralkyl group.
R^{b}

R^{b} represents an alkyl group (the number of carbon atoms is preferably 1 to 12, more preferably in the range of 1 to 6, and particularly preferably in the range of 1 to 3) or an alkenyl group (the number of carbon atoms is preferably in the range of 2 to 12 and more preferably in the range of 2 to 6). Among these, it is preferable that R^{b} represents a methyl group or an ethyl group.

L^{a}

L^{a} represents a linking group. L^{a} represents an alkylene group (the number of carbon atoms is preferably in the range of 1 to 12, more preferably in the range of 1 to 6, and particularly preferably in the range of 1 to 3), a carbonyl group, an imino group (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, an alkylene group or a carbonyl group is preferable, a methylene group, an ethylene group, a propylene group, or a carbonyl group is more preferable, a methylene group or an ethylene group is still more preferable, and a methylene group is particularly preferable.

L^{b}

L^{b} represents a single bond, an alkylene group (the number of carbon atoms is preferably in the range of 1 to 12, more preferably in the range of 1 to 6, and particularly preferably in the range of 1 to 3), a carbonyl group, an imino group (NR^{N}) (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, a single bond, a methylene group, an ethylene group, a propylene group, or a carbonyl group is preferable and a single bond, a methylene group, or an ethylene group is preferable.

R^{c}

R^{c} represents a hydrogen atom or an alkyl group (the number of carbon atoms is preferably in the range of 1 to 12, more preferably in the range of 1 to 6, and particularly preferably in the range of 1 to 3). Among these, it is preferable that R^{e} represents a hydrogen atom or a methyl group. In Formula (a-1), R^{c} may represent a graft type polymer formed by introducing a polymer chain to this site or a polymer constituting a mesh network.

n

n represents an integer of 0 or greater. The upper limit of n is the number of respective substitutable cyclic structural portions. For example, the number is 4 in a case of the following Formulae (5-1) to (5-4) and the number is 3 in a case of Formulae (6-5) and (6-6).

M₁₁⁻

M₁₁⁻ represents a counter anion, and examples thereof include an hydroxide ion or a halogen anion.

A ring Q1 represents a nitrogen-containing heterocycle, and a nitrogen-containing saturated heterocycle is preferable and a 5- or 6-membered ring nitrogen-containing saturated heterocycle is more preferable. Specifically, as the cyclic structure, the following Formulae (5-1) to (5-6) are preferable.

A ring Q2 represents a nitrogen-containing heterocycle, and a nitrogen-containing unsaturated heterocycle is preferable, a 5- or 6-membered ring nitrogen-containing unsaturated heterocycle is more preferable, and a pyrrolyl group, a pyrazolyl group, an imidazolyl group, a triazolyl group, a pyridyl group, or a pyrimidyl group (all of these, bonded at a C-position) is still more preferable. Specifically, as the cyclic structure, the following Formulae (6-1) to (6-11) are preferable.

A ring Q3 represents a nitrogen-containing heterocycle, and a nitrogen-containing unsaturated heterocycle is preferable, a 5-membered ring nitrogen-containing unsaturated heterocycle is preferable, and a pyrrolyl group, an imidazolyl group, a pyrazolyl group, or a triazolyl group (all of these, bonded at a N-position) is preferable. Specifically, as the cyclic structure, the following Formulae 8-1 to 8-3 are preferable.

The symbol “*” in the formulae indicates a binding position.

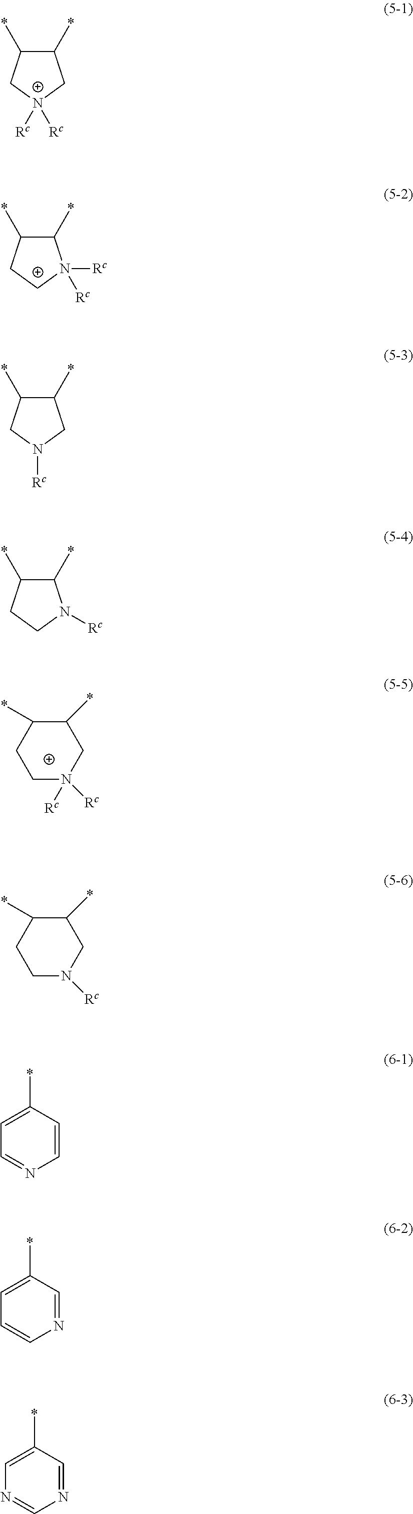

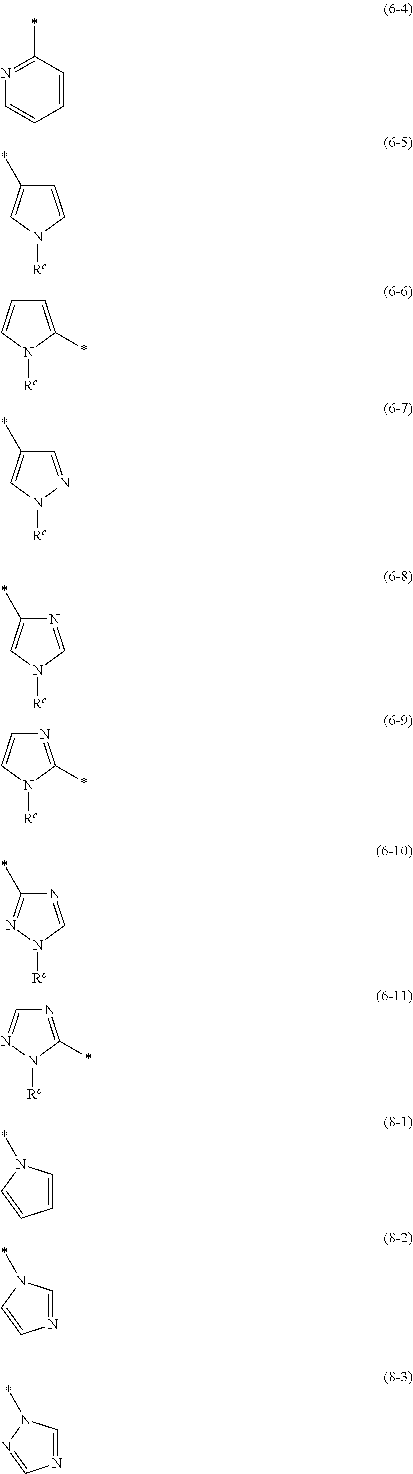

All of the above-described cyclic structural groups may be accompanied by a predetermined number of substituents Ra. In the formulae, an onium may become a salt. Further, in Formulae 6-5 to 6-11, the cyclic structural group may indicate an onium or a salt.

A plurality of R^{a}'s, R^{b}'s, R^{c}'s, L^{a}'s, and L^{b}'s are present in a molecule, and these may be the same as or different from each other. The plurality of R^{a}'s, R^{b}'s, and R^{c}'s may be bonded to each other and form a ring. Further, although not particularly noted, substituents or linking groups adjacent to each other may be bonded to each other to form a ring within the range not impairing the effects of the present invention.

Further, it is preferable that the nitrogen-containing organic compound is a compound represented by the following Formula (b).

R^{c}₂N-[L^{d}-N(R^{c})]ₘ-L^{d}-NR^{c}₂ (b)

In the formula, R^{e} has the same definition as that described above. m represents an integer of 0 or greater, and is preferably 1 or greater, more preferably 2 or greater, and still more preferably 3 or greater. The upper limit is not particularly limited, but is practically 10 or less and more practically 6 or less.

L^{d} represents an alkylene group (the number of carbon atoms is preferably in the range of 1 to 12, more preferably in the range of 1 to 6, and particularly preferably in the range of 1 to 3), a carbonyl group, an imino group (NR^{N}) (the number of carbon atoms is preferably in the range of 0 to 6 and more preferably in the range of 0 to 3), an arylene group (the number of carbon atoms is preferably in the range of 6 to 22 and more preferably in the range of 6 to 14), a heterocyclic group (the number of carbon atoms is preferably in the range of 1 to 12 and more preferably in the range of 2 to 5), or a combination of these. Among these, an alkylene group is preferable, and a methylene group, an ethylene group, or a propylene group is more preferable.

Further, a plurality of R^{e}'s and L^{d}'s may be the same as or different from each other. The plurality of R^{e}'s and L^{d}'s may be bonded to each other to form a ring.

It is preferable that the above-described nitrogen-containing organic compound is a compound described below or a compound having a repeating unit. However, the present invention is not limitatively interpreted thereto. In addition, those having a cationic group may have a counter anion. Examples of the counter anion are the same as those of M₁₁⁻ described above.

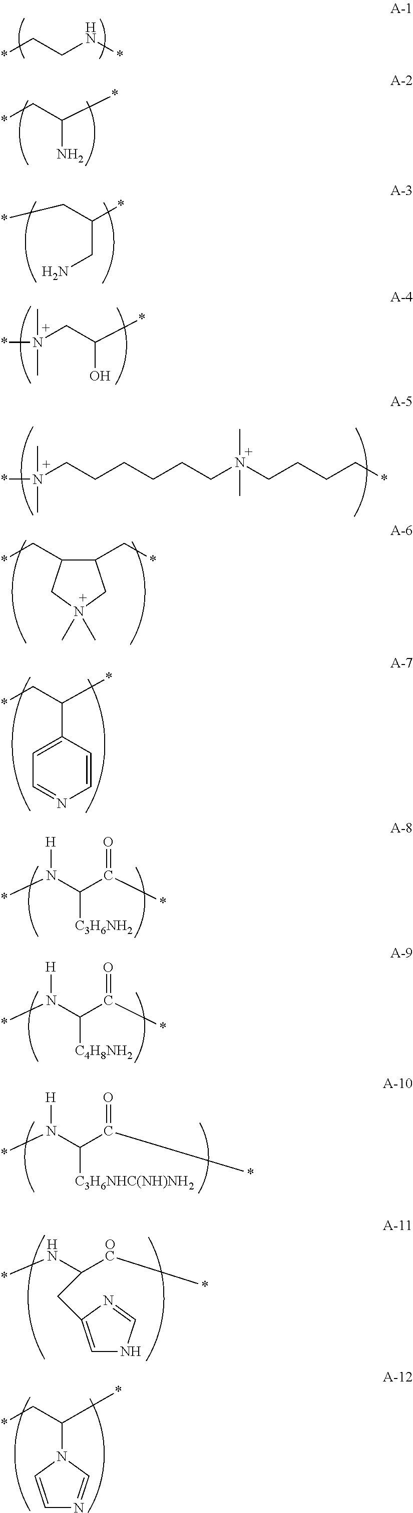

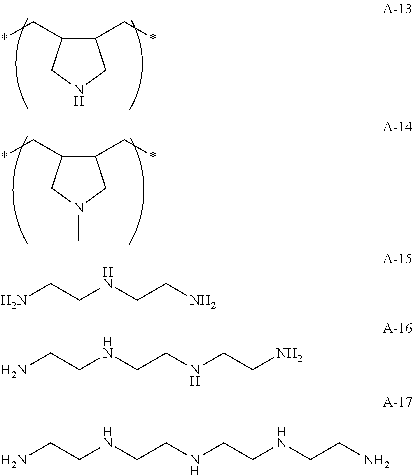

A-1: polyethylene imine

A-2: polyvinylamine

A-3: polyallylamine

A-4: dimethylamine-epihydrin-based polymer

A-5: polyhexadimethrine

A-6: polydimethyl diallyl ammonium (salt)

A-7: poly(4-vinylpyridine)

A-8: polyornithine

A-9: polylysine

A-10: polyarginine

A-11: polyhistidine

A-12: polyvinyl imidazole

A-13: polydiallylamine

A-14: polymethyl diallylamine

A-15: diethylenetriamine

A-16: triethylenetetramine

A-17: tetraethylenepentamine

A-18: pentaethylenehexamine

B-1: 1,1-dimethylhydrazine

B-2: 3,4-dihydroxybenzoic acid

B-3: 6-O-palmitoyl-L-ascorbic acid

B-4: N,N-diethylhydroxylamine

B-5: N-hydroxyphthalimide

B-6: resorcinol

B-7: N-methylhydroxylamine

B-8: adipohydrazide

B-9: ascorbic acid

B-10: acetamide oxime

B-11: acetoxime

B-12: acetohydrazide

B-13: aminoguanidine

B-14: catechol

B-15: methyl carbazic acid

B-16 carbohydrazide

B-17: glyoxylic acid

B-18: oxalic acid

B-19: semicarbadize

B-20: tetrabutylammonium

B-21: dodecyl pyridinium

B-22: hydroxyurea

B-23: pyrogallol

B-24: phloroglucin dihydrate

B-25: hexadecyl trimethyl ammonium

B-26: gallic acid

B-27: methyl gallate

In Formula A-1, NH may represent a graft type polymer formed by introducing a polymer chain to this site of a hydrogen atom or a polymer constituting a mesh network.

The preferable blending amount of the above-described anticorrosive components varies depending on an action of the anticorrosive components, and the anticorrosive components are classified into an inhibitor type and a reducing agent type to be described later. The content of an inhibitor-type compound in the stripper is preferably 0.01% by mass or greater, more preferably 0.05% by mass or greater, and particularly preferably 0.1% by mass or greater. The upper limit thereof is preferably 10% by mass or less, more preferably 5% by mass or less, still more preferably 2% by mass or less, and particularly preferably 1% by mass or less. One advantage of the inhibitor-type compound is that the anticorrosive effects are exhibited using a trace amount of the inhibitor-type compound. The content of the reducing agent-type compound in the stripper is preferably 0.5% by mass or greater, more preferably 1% by mass or greater, and particularly preferably 2% by mass or greater. The upper limit thereof is preferably 50% by mass or less, more preferably 30% by mass or less, and particularly preferably 20% by mass or less.

The above-described anticorrosive components may be used alone or in combination of two or more kinds thereof.

When the anticorrosive component is an oligomer or a polymer, it is preferable that the molecular weight thereof is appropriately adjusted. For example, in compounds represented by Formulae (7) to (9), the molecular weight thereof is preferably 500 or greater and more preferably 1000 or greater. The upper limit thereof is preferably 100,000 or less and more preferably 10,000 or less.

The weight average molecular weight of a polymer compound is measured by gel permeation chromatography (GPC) in terms of standard polystyrene. Basically, a method of using a column obtained by connecting three sheets of TOSOH TSKgel Super AWM-H to each other as a column and 10 mM of LiBr/N-methylpyrrolidone as an eluent; or a method of using a column obtained by connecting TOSOH TSKgel Super HZM-H, TOSOH TSKgel Super HZ4000, and TOSOH TSKgel Super HZ2000 to each other as a column and tetrahydrofuran as an eluent can be used as the measurement method. In this case, an eluent suitable for the type of a polymer may be appropriately selected and then used.

The anticorrosive component can be classified into two types based on the mechanism of the estimated action thereof. The two types are an inhibitor-type compound that is considered to be adsorbed to the surface of a germanium layer and to exhibit the anticorrosive effects and a reducing agent-type compound that suppresses elution of germanium. In the reducing agent type, since germanium has properties of being eluted due to oxidation, it is considered that a function of suppressing the influence thereof in the system is exhibited. There is a possibility that the compounds represented by Formulae (1) and (7) to (10) are acted as inhibitor-type compounds. Meanwhile, there is a possibility that the compounds represented by Formulae (2) to (6) and (11) are acted as reducing agent-type compounds.

It is considered that an inhibitor-type compound exhibits a function of protecting Ge because the compound contains a nitrogen (N) atom. This can be confirmed by quantifying the surface of a sample that is allowed to be adsorbed to the surface of Ge through ESCA measurement. When the N/Ge ratio before the treatment is compared to the N/G ratio after the treatment, adsorption of the anticorrosive component is confirmed in the case where the N/Ge ratio after the treatment is greater. As the adsorption amount thereof is larger, this means that a large amount of inhibitor-type compound (anticorrosive component) is adsorbed, which is more preferable in terms of protection of the surface of Ge. It is preferable that the N/Ge ratio is increased by 50% or greater, more preferable that the N/Ge ratio is increased by 100% or greater, and still more preferable that the N/Ge ratio is increased by 200% or greater. The upper limit thereof is not particularly limited, but the upper limit of 1000% or less is practical.

It is understood that the reducing agent-type compound (anticorrosive component) that suppresses elution of germanium increases the surface potential of the surface of Ge to the positive side when added thereto. Since the absolute value thereof changes depending on the environmental conditions, it is difficult to specifically define the potential range thereof, but the potential is assumed to be appropriately changed by the addition of a reducing agent. This can be confirmed by an increase of the surface potential to the positive side when compared to the surface potential before the treatment in a case where the surface potential of the surface of Ge is measured when an additive is used together. As the surface potential is further increased to the positive side, it is understood that Ge is unlikely to be oxidized (enters a reduced state). As a preferred embodiment, it is preferable that the surface potential thereof is increased by 0.2 mV or greater, more preferable that the surface potential thereof is increased by 0.3 mV or greater, and still more preferable that the surface potential thereof is increased by 0.5 mV or greater. The upper limit thereof is not particularly limited, but an upper limit of 1.5 mV or less is practical.

It is preferable that the stripper of the present invention contains a silicon compound as an anticorrosive component of polysilicon. Among the compounds, an alkoxysilane compound is suitably used as an anticorrosive, and preferred examples thereof include tetraethoxysilane, tetramethoxysilane, methyl trimethoxysilane, methyl triethoxysilane, ethyl trimethoxysilane, ethyl triethoxysilane, phenyl trimethoxysilane, diphenyl dimethoxysilane, N-2-(aminoethyl)-3-aminopropyl methyl dimethoxysilane, N-2-(aminoethyl)-3-aminopropyl trimethoxysilane, 3-aminopropyl trimethoxysilane, 3-aminopropyl triethoxysilane, and N-phenyl-3-aminopropyl trimethoxysilane. Among these, N-2-(aminoethyl)-3-aminopropyl methyl dimethoxysilane or N-2-(aminoethyl)-3-aminopropyl trimethoxysilane which has an amino group is preferable.

It is preferable that the silicon compound is a compound represented by the following Formula (S1).

R^{S1}₄Si (S1)

In the formula, R^{S1} represents an alkyl group having 1 to 10 carbon atoms (the number of carbon atoms is preferable in a range of 1 to 3), an alkoxy group having 1 to 10 carbon atoms (the number of carbon atoms is preferable in a range of 1 to 3), an aryl group having 6 to 22 carbon atoms (the number of carbon atoms is preferably 6 to 10), an aryloxy group having 6 to 22 carbon atoms (the number of carbon atoms is preferable in a range of 6 to 10), an alkenyl group having 2 to 10 carbon atoms (the number of carbon atoms is preferably in a range of 2 to 4) (preferably a vinyl group or an allyl group), an acyloxy group having 1 to 10 carbon atoms (the number of carbon atoms in a range of 1 to 3), an aryloyloxy group having 7 to 25 carbon atoms (the number of carbon atoms is preferably 7 to 11), an oxime group having 2 to 10 carbon atoms (the number of carbon atoms is preferably in a range of 2 to 4), or a hydrogen atom. In this case, all of R^{S1}'s do not represent a hydrogen atom. It is preferable that at least one of four R^{S1}'s represents an alkoxy group.

R^{S1} may further have a substituent, and preferred examples thereof include an amino group (an amino group that does not have carbon atoms, an alkylamino group having 1 to 10 carbon atoms, or an arylamino group having 6 to 18 carbon atoms is preferable), a hydroxyl group, a carboxyl group, a glycidyl group, and an oxetane group. Further, R^{S2} and R^{S3} may also further have a substituent and the preferred ranges thereof are the same as described above. In addition, the alkyl group and the alkenyl group of these substituents may be linear, branched, or cyclic.

Other substituents described above may be groups represented by the following Structural Formula (S1-N).

-(L¹-NR^{N})ₙ—R^{N}₂ (S1-N)

L¹ represents an alkylene group having 1 to 6 carbon atoms. R^{N} has the same definition as that described above. n represents an integer of 1 to 6.

Alkoxysilane

As an organic silicon compound, alkyl (mono, di, tri)alkoxysilane or tetraalkoxysilane (hereinafter, referred to as specific alkoxysilane compounds) is preferable. As the specific alkoxysilane compounds, compounds represented by the following Formula (S2) are preferable.

R^{S2}ₘ₁Si(OR^{S3})ₘ₂ (S2)

R^{S2} represents an alkyl group having 1 to 10 carbon atoms (the number of carbon atoms is preferably in a range of 1 to 3), an alkenyl group having 2 to 10 carbon atoms (the number of carbon atoms is preferably in a range of 2 to 4), or an aryl group having 6 to 22 carbon atoms (the number of carbon atoms is preferably in a range of 6 to 10). When a plurality of R^{S2}'s are present, R^{S2}'s may be the same as or different from each other. Among the examples, an alkyl group is preferable, and examples thereof include a methyl group, an ethyl group, a propyl group, and an isopropyl group. Further, a methyl group or an ethyl group is preferable and a methyl group is particularly preferable.

R^{S3} represents an alkyl group having 1 to 10 carbon atoms or an aryl group having 6 to 22 carbon atoms (the number of carbon atoms is preferably in a range of 6 to 10). When a plurality of R^{S3}'s are present, R^{S3}'s may be the same as or different from each other. Among these, an alkyl group having 1 to 4 carbon atoms (the number of carbon atoms is more preferably in a range of 1 to 3) is more preferable.

R^{S2} may further have a substituent, and examples of the substituent are the same as the substituents which may be included in R^{S1} described above. It is preferable that at least one R^{S2} has an optional substituent (for example, a group represented by Formula (S1-N)).

m1 and m2 represent an integer of 1 to 3 and “m1+m2” is 4. A dialkoxysilane compound in which m1 represents 2 and m2 represents 2 or a trialkoxysilane compound in which m1 represents 1 and m2 represents 3 is preferable.

The content of the silicon compound in the stripper is preferably 0.01% by mass or greater, more preferably 0.05% by mass or greater, and particularly preferably 0.1% by mass or greater. The upper limit thereof is not particularly limited, but is preferably 30% by mass or less, more preferably 20% by mass or less, still more preferably 10% by mass or less, even still more preferably 5% by mass or less, and particularly preferably 1% by mass or less. When the content thereof is set to be the upper limit or less, the removability of the resist is not excessively degraded, which is preferable. When the content thereof is set to the lower limit or greater, excellent anticorrosion properties can be obtained, which is preferable.

(pH Regulator)

In a treatment liquid of the present invention, a pH regulator may be used in order for the pH thereof to be in a desired range. It is preferable that tetramethylammonium, quaternary ammonium salts such as choline, alkali hydroxides such as potassium hydroxide, alkaline-earth salts, 2-aminoethanol, or an amino compound such as guanidine is used as the pH regulator for the purpose of increasing the pH value. Examples of the pH regulator used to decrease the pH value include inorganic acids such as carbonic acid, hydrochloric acid, nitric acid, sulfuric acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid.

The amount of the pH regulator to be used is not particularly limited as long as an amount thereof required for adjusting the pH to be in the above-described range is used.

The pH regulator may be used alone or in combination of two or more kinds thereof.

The display of compounds in the present specification (for example, when a compound is referred to by being added at the end of the compound) is used to include the compound itself, a salt thereof, and an ion thereof. Further, the display thereof includes a derivative which is partially changed by being esterified or introducing a substituent within a range in which desired effects can be exhibited.

A substituent (the same applies to a linking group) in which substitution or unsubstitution is not specified in the present specification means that an arbitrary substituent may be included in the group. The same applies to a compound in which substitution or unsubstitution is not specified. As a preferred substituent, the substituent T described below is exemplified.

Examples of the substituent T include the followings.

Examples thereof include an alkyl group (preferably an alkyl group having 1 to 20 carbon atoms such as methyl, ethyl, isopropyl, t-butyl, pentyl, heptyl, 1-ethylpentyl, benzyl, 2-ethoxyethyl, or 1-carboxymethyl), an alkenyl group (preferably, an alkenyl group having 2 to 20 carbon atoms such as vinyl, allyl, or oleyl), an alkynyl group (preferably an alkynyl group having 2 to 20 carbon atoms such as ethynyl, butadiynyl, or phenylethynyl), a cycloalkyl group (preferably a cycloalkyl group having 3 to 20 carbon atoms such as cyclopropyl, cyclopentyl, cyclohexyl, or 4-methylcyclohexyl), an aryl group (preferably an aryl group having 6 to 26 carbon atoms such as phenyl, 1-naphthyl, 4-methoxyphenyl, 2-chlorophenyl, or 3-methylphenyl), a heterocyclic group (preferably a heterocyclic group having 2 to 20 carbon atoms or preferably a heterocyclic ring of a 5- or 6-membered ring having at least one of an oxygen atom, a sulfur atom and a nitrogen atom such as 2-pyridyl, 4-pyridyl, 2-imidazolyl, 2-benzimidazolyl, 2-thiazolyl, or 2-oxazolyl), an alkoxy group (preferably an alkoxy group having 1 to 20 carbon atoms such as methoxy, ethoxy, isopropyloxy, or benzyloxy), an aryloxy group (preferably an aryloxy group having 6 to 26 carbon atoms such as phenoxy, 1-naphthyloxy, 3-methylphenoxy, or 4-methoxyphenoxy), an alkoxycarbonyl group (preferably an alkoxycarbonyl group having 2 to 20 carbon atoms such as ethoxycarbonyl or 2-ethylhexyloxycarbrbonyl), an amino group (preferably an amino group having 0 to 20 carbon atoms, an alkylamino group having 0 to 20 carbon atoms, or an arylamino group having 0 to 20 carbon atoms such as amino, N,N-dimethylamino, N,N-diethylamino, N-ethylamino, or anilino), a sulfamoyl group (preferably a sulfamoyl group having 0 to 20 carbon atoms such as N,N-dimethylsulfamoyl or N-phenylsulfamoyl), an acyl group (preferably an acyl group having 1 to 20 carbon atoms such as acetyl, propionyl, butyryl, or benzoyl), an acyloxy group (preferably an acyloxy group having 1 to 20 carbon atoms such as acetyloxy or benzoyloxy), a carbamoyl group (preferably a carbamoyl group having 1 to 20 carbon atoms such as N,N-dimethylcarbamoyl or N-phenylcarbamoyl), an acylamino group (preferably an acylamino group having 1 to 20 carbon atoms such as acetylamino or benzoylamino), an alkylthio group (preferably an alkylthio group having 1 to 20 carbon atoms such as methylthio, ethylthio, isopropylthio, or benzylthio), an arylthio group (preferably an arylthio group having 6 to 26 carbon atoms such as phenylthio, 1-naphthylthio, 3-methylphenylthio, or 4-methoxyphenylthio), alkyl or an arylsulfonyl group (preferably alkyl or an arylsulfonyl group having 1 to 20 carbon atoms such as methylsulfonyl, ethylsulfonyl, or benzenesulfonyl), and a hydroxyl group, a sulfanyl group, a cyano group, and a halogen atom (such as a fluorine atom, a chlorine atom, a bromine atom, or an iodine atom). Among these, an alkyl group, an alkenyl group, an aryl group, a heterocyclic group, an alkoxy group, an aryloxy group, an alkoxycarbonyl group, an amino group, an acylamino group, a hydroxyl group or a halogen atom is more preferable. Further, an alkyl group, an alkenyl group, a heterocyclic group, an alkoxy group, an alkoxycarbonyl group, an amino group, an acylamino group, or a hydroxyl group is particularly preferable.

Moreover, respective groups exemplified in these substituents T may be further substituted with the above-described substituents T.

When a compound or a substituent and a linking group include an alkyl group, an alkylene group, an alkenyl group, an alkenylene group, an alkynyl group, or an alkynylene group, these may be cyclic, chain-like, linear, or branched and may be substituted or unsubstituted as described above. Moreover, when an aryl group and a heterocyclic group are included, these may be a single ring or a condensed ring and may be substituted or unsubstituted.

In the present specification, each of the technical matters such as the temperature or the thickness including options of substituents or linking groups of compounds can be used in combination even through the lists thereof are respectively and independently described.

Respective substituents defined in the present specification may be substituted through a linking group L described below within the range in which the effects of the present invention are exhibited or the linking group L may exist in the structure thereof. A hetero linking group described below may exist in the structure of, for example, an alkyl group, an alkylene group, an alkenyl group, or an alkenylene group.

Preferred examples of the linking group L include a hydrocarbon linking group [an alkylene group having 1 to 10 carbon atoms (the number of carbon atoms is preferably in a range of 1 to 6 and more preferably in a range of 1 to 3), an alkenylene group having 2 to 10 carbon atoms (the number of carbon atoms is preferably in a range of 2 to 6 and more preferably in a range of 2 to 4), an alkynylene group having 2 to 10 carbon atoms (the number of carbon atoms is preferably in a range of 2 to 6 and more preferably in a range of 2 to 4), an arylene group having 6 to 22 carbon atoms (the number of carbon atoms is preferably in a range of 6 to 10), or a combination of these], a hetero linking group [a carbonyl group (—CO—), a thiocarbonyl group (—CS—), an ether group (—O—), a thioether group (—S—), an imino group (—NR^{N}—), an ammonium linking group (—NR^{N}₂⁺—), a polysulfide group (the number of S′ is in a range of 1 to 8), an imine linking group (R^{N}—N═C< or —N═C(R^{N})—), a sulfonyl group (—SO₂—), a sulfinyl group (—SO—), a phosphoric acid linking group (—O—P(OH)(O)—O—), a phosphonic acid linking group (—P(OH)(O)—O—), or a combination of these], or a linking group combining these groups. Moreover, in a case where substituents or linking groups are condensed to each other and form a ring, the above-described hydrocarbon linking groups may form a double bond or a triple bond to be linked to each other. As a ring to be formed, a 5- or 6-membered ring is preferable. A nitrogen-containing 5-membered ring is preferable as a 5-membered ring, and examples of a compound that forms the ring include pyrrole, imidazole, pyrazole, indazole, indole, benzimidazole, pyrrolidine, imidazolidine, pyrazolidine, indoline, carbazole, and derivatives of these. Examples of a 6-membered ring include piperidine, morpholine, piperazine, and derivatives of these. When the 6-membered ring includes an aryl group or a heterocyclic group, the 6-membered ring may be a single ring or a condensed ring and may be substituted or unsubstituted.

R^{N} has the same definition as that described above.

R^{P} represents a hydrogen atom, a hydroxyl group, or a substituent. Preferred examples of the substituent include an alkyl group (the number of carbon atoms is preferably in a range of 1 to 24, more preferably in a range of 1 to 12, still more preferably in a range of 1 to 6, and particularly preferably in a range of 1 to 3), an alkenyl group (the number of carbon atoms is preferably in a range of 2 to 24, more preferably in a range of 2 to 12, still more preferably in a range of 2 to 6, and particularly preferably 2 or 3), an alkynyl group (the number of carbon atoms is preferably in a range of 2 to 24, more preferably in a range of 2 to 12, still more preferably in a range of 2 to 6, and particularly preferably 2 or 3), an aralkyl group (the number of carbon atoms is preferably in a range of 7 to 22, more preferably in a range of 7 to 14, and particularly preferably in a range of 7 to 10), an aryl group (the number of carbon atoms is preferably in a range of 6 to 22, more preferably in a range of 6 to 14, and particularly preferably in a range of 6 to 10), an alkoxy group (the number of carbon atoms is preferably in a range of 1 to 24, more preferably in a range of 1 to 12, still more preferably in a range of 1 to 6, and particularly preferably in a range of 1 to 3), an alkenyloxy group (the number of carbon atoms is preferably in a range of 2 to 24, more preferably in a range of 2 to 12, still more preferably in a range of 2 to 6, and particularly preferably 2 or 3), an alkynyloxy group (the number of carbon atoms is preferably in a range of 2 to 24, more preferably in a range of 2 to 12, still more preferably in a range of 2 to 6, and particularly preferably 2 or 3), an aralkyloxy group (the number of carbon atoms is preferably in a range of 7 to 22, more preferably in a range of 7 to 14, and particularly preferably in a range of 7 to 10), and an aryloxy group (the number of carbon atoms is preferably in a range of 6 to 22, more preferably in a range of 6 to 14, and particularly preferably in a range of 6 to 10).

The number of atoms constituting the linking group L is preferably in a range of 1 to 36, more preferably in a range of 1 to 24, still more preferably in a range of 1 to 12, and particularly preferably in a range of 1 to 6. The number of linking atoms of a linking group is preferably 10 or less and more preferably 8 or less. The lower limit thereof is 1 or greater. The number of linking atoms indicates the minimum number of atoms that are positioned in a path connecting predetermined structural units to each other and are involved in the linkage. For example, in a case of —CH₂—C(═O)—O—, the number of atoms constituting the linking group is 6, but the number of linking atoms is 3.

Specific examples of a combination of linking groups include an oxycarbonyl group (—OCO—), a carbonate group (—OCOO—), an amide group (—CONH—), a urethane group (—NHCOO—), a urea group (—NHCONH—), a (poly)alkyleneoxy group (—(Lr—O)x-), a carbonyl (poly)oxyalkylene group (such as —CO—(O—Lr)x- or a carbonyl (poly)alkyleneoxy group (—CO—(Lr—O)x-), a carbonyloxy (poly)alkyleneoxy group (—COO—(Lr—O)x-), a (poly)alkyleneamino group (—(Lr—NR^{N})x), an alkylene (poly)iminoalkylene group (—Lr—(NR^{N}—Lr)x-), a carbonyl (poly)iminoalkylene group (—CO—(NR^{N}—Lr)x-), a carbonyl (poly)alkyleneimino group (—CO—(Lr—NR^{N})x-), a (poly)ester group (such as —(CO—O—Lr)x-, —(O—CO—Lr)x-, —(O—Lr—CO)x-, —(Lr—CO—O)x-, —(Lr—O—CO)x-), and a (poly)amide group (such as —(CO—NR^{N}—Lr)x-, —(NR^{N}—CO—Lr)x-, —(NR^{N}—Lr—CO)x-, —(Lr—CO—NR^{N})x-, or —(Lr—NR^{N}—CO)x-). x represents an integer of 1 or greater, preferably an integer of 1 to 500, and more preferably an integer of 1 to 100.

It is preferable that Lr represents an alkenylene group or an alkynylene group. The number of carbon atoms is preferably in a range of 1 to 12, more preferably in a range of 1 to 6, and particularly preferably in a range of 1 to 3 (alkenylene group, the number of carbon atoms is 2 or more in a case of an alkynylene group). A plurality of Lr's, R^{N}'s, R^{P}'s, and x's are not necessarily the same as each other. The direction of the linking group is not limited to the above-described order and the direction thereof may be made according to a predetermined appropriate chemical formula.

(pH)

The pH of the stripper of the present invention is preferably 5 or greater, more preferably 7 or greater, and particularly preferably 10 or greater. The upper limit thereof is preferably 16 or less and more preferably 15 or less. When the pH thereof is in the above-described range, it is possible to achieve both of excellent release properties and protection of the Ge-containing layer. Further, unless otherwise noted, the measurement conditions of the pH value are as described in the examples below.

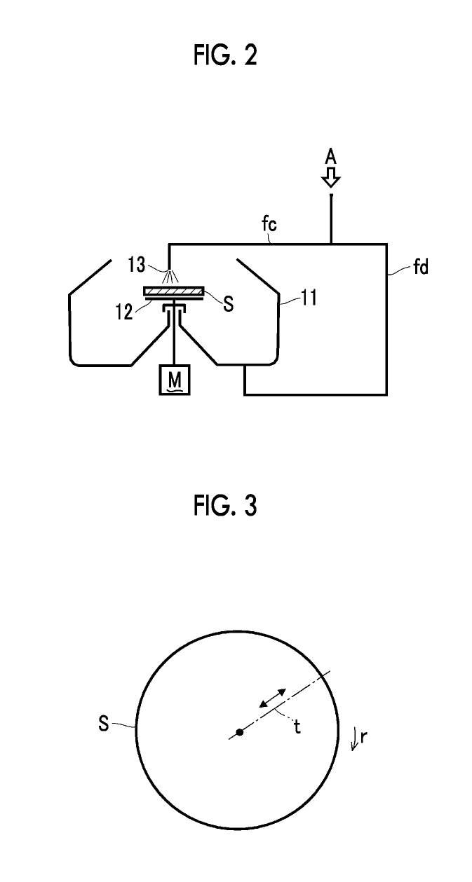

The manner of application of the stripper is not particularly limited, but it is preferable that the stripper is circulated through channels, ejected or sprayed from an ejection opening, and is brought into contact with the semiconductor substrate. When this process is described with reference to FIG. 2, the prepared stripper is introduced from an introduction port A, transitioned to an ejection opening 13, sprayed from the ejection opening 13, and then applied to the upper surface of a semiconductor substrate S in a treatment container (treatment tank) 11. In the embodiment shown in the same figure, the stripper is transitioned to the ejection opening 13 through a channel fc. A channel fd indicates a returning path for reusing a liquid chemical. It is preferable that the semiconductor substrate S is on a rotary table 12 and rotates along with the rotary table by a rotation driving unit M.

Moreover, in the stripper of the present invention, it is preferable that the amount of impurities, for example, metals, in the solution is small when the usage of the stripper is considered. Particularly, the ion concentration of Na, K, and Ca in the stripper is preferably in the range of 1 ppt to 1 ppm (on a mass basis). Further, in the stripper, the number of coarse particles having an average particle diameter of 0.5 μm or greater is preferably 100/cm³ or less and more preferably 50/cm³ or less.

(Container)

The stripper of the present invention fills an arbitrary container to be stored, is transported, and then used as long as corrosion resistance is not a problem. Further, a container whose cleanliness is high and in which impurities are not largely eluted is preferable for the purpose of using the container for a semiconductor. As a usable container, “Clean bottle” series (manufactured by ACELLO CORPORATION) or “Pure bottle” (manufactured by KODAMA PLASTICS Co., Ltd.) is exemplified, but the examples are not limited thereto.

[Treatment Conditions]

In the present invention, it is preferable to use a sheet type device. Specifically, as the sheet type device, a device which has a treatment tank and in which the semiconductor substrate is transported or rotated in the treatment tank, the stripper is provided (ejection, spray, falling, dropping, or the like) in the treatment tank, and the stripper is brought into contact with the semiconductor substrate is preferable.

Advantages of the sheet type device are as follows: (i) a fresh stripper is constantly supplied and thus reproducibility is excellent and (ii) in-plane uniformity is high.

The sheet type device is preferably provided with a nozzle in the treatment tank thereof and a method for ejecting the stripper to the semiconductor substrate by swinging the nozzle in the plane direction of the semiconductor substrate is preferable. In this manner, deterioration of the solution can be prevented, which is preferable.

The treatment temperature is preferably 10° C. or higher, more preferably 20° C. or higher, still more preferably 30° C. or higher, and particularly preferably 40° C. or higher. The upper limit thereof is preferably 100° C. or lower, more preferably 80° C. or lower, and particularly preferably 70° C. or lower. In addition, the treatment temperature is based on the temperature applied to the substrate in a method for measuring the temperature described in the examples below. The treatment temperature may be set to the temperature in a tank in a case of the storage temperature or the temperature being managed during a batch treatment and may be set to the temperature in a circulation channel in a case of the temperature being managed by a circulatory system.

The supply rate of the stripper is not particularly limited, but is preferably in the range of 0.05 L/min to 5 L/min and more preferably in the range of 0.1 L/min to 3 L/min. It is preferable that the supply rate thereof is set to be greater than or equal to the lower limit because the in-plane uniformity of the treatment can be more excellently secured. It is preferable that the rate thereof is set to be less than or equal to the upper limit because the performance stabilized at the time of performing a treatment continuously can be secured. The rotation of the semiconductor substrate also depends on the size thereof and the semiconductor substrate rotates preferably at 50 rpm to 1000 rpm from the same viewpoint described above.

In a sheet type treatment according to the preferred embodiment of the present invention, it is preferable that the semiconductor substrate is transported or rotated in a predetermined direction and a stripper is brought into contact with the semiconductor substrate by spraying the stripper to the space of the semiconductor substrate. The supply rate of the stripper and the rotation rate of the substrate are the same as those described above.

In the configuration of the sheet type device according to the preferred embodiment of the present invention, it is preferable that the stripper is provided while the ejection opening (nozzle) is moved as illustrated in FIG. 3. Specifically, in the present embodiment, the substrate is rotated in an r direction when the stripper is applied to the semiconductor substrate S. Further, the ejection opening is set to move along a movement locus line t extending to the end portion from the central portion of the semiconductor substrate. In this manner, the rotation direction of the substrate and the movement direction of the ejection opening are set to be different from each other in the present embodiment and thus both are set to be relatively moved. As the result, the stripper can be evenly provided for the entire surface of the semiconductor substrate and the uniformity of the treatment is suitably secured.

The moving speed of the ejection opening (nozzle) is not particularly limited, but is preferably 0.1 cm/s or greater and more preferably 1 cm/s or greater. The upper limit thereof is preferably 30 cm/s or less and more preferably 15 cm/s or less. The movement locus line may be linear or curved (for example, ark-shaped). In both cases, the movement speed can be calculated from the distance of an actual locus line and the time spent for the movement thereof. The time required for treating one sheet of substrate is preferably in the range of 10 seconds to 300 seconds.

An etching rate [R1] of a layer (Ge-containing layer) containing germanium or the silicide layer thereof is not particularly limited, but it is preferable that the layer is not excessively removed due to the application of the stripper. Specifically, the etching rate thereof is preferably 200 Å/min or less, more preferably 100 Å/min or less, still more preferably 50 Å/min or less, even still more preferably 20 Å/min or less, and particularly preferably 10 Å/min or less. The lower limit thereof is not particularly limited, but is practically 1 Å/min or greater when the measurement limit is considered.

An etching rate [R2] of a layer (polysilicon-containing layer) containing polysilicon is not particularly limited, but it is preferable that the layer is not excessively removed due to the application of the stripper. Specifically, the etching rate thereof is preferably 200 Å/min or less, more preferably 100 Å/min or less, still more preferably 50 Å/min or less, even still more preferably 20 Å/min or less, and particularly preferably 10 Å/min or less. The lower limit thereof is not particularly limited, but is practically 1 Å/min or greater when the measurement limit is considered.

Further, since damages of a metal electrode layer such as Al, Cu, Ti, or W and an insulating film layer such as HfOₓ, HfSiOₓ, WOₓ, AlOₓ, SiOₓ, SiOC, SiON, TiN, or SiN can be suitably suppressed, the stripper according to the preferred embodiment of the present invention is preferably used for a semiconductor substrate including these layers. Further, in the present specification, in a case where the composition of a metal compound is mentioned by the combination of the elements, this means that metal compounds with arbitrary compositions are broadly included. For example, SiOC (SiON) does not mean that the ratio of the amounts of Si, O, and C(N) is 1:1:1 but means that Si, O, and C(N) coexist. The same applies throughout the present specification and also to other metal compounds.

[Resist]

The resist to be applied to the present invention is not particularly limited, and known resist materials are used. For example, a positive type resist, a negative type resist, and a positive-negative compatible type photoresist are exemplified. Specific examples of the positive type resist include a vinyl cinnamate-based resist, a cyclization polyisobutylene-based resist, an azo-novolak resin-based resist, and a diazoketone-novolak resin-based resist. Further, specific examples of the negative type resist include an azide-cyclization polyisoprene-based resist, an azide-phenolic resin-based resist, and a chloromethyl polystyrene-based resist. Further, specific examples of the positive-negative compatible type photoresist include a poly(p-butoxycarbonyloxystyrene)-based photoresist.

In the present invention, among these, the positive type resist is preferable. Particularly, a positive type resist including at least one of a novolak resin or a polyhydroxystyrene resin is effectively stripped. In addition, since the stripper of the present invention has excellent performance, the stripper is effective for stripping of a resist layer having a film thickness of 5 μm to 500 μm.

As the positive type resist including at least one of a novolak resin and a polyhydroxystyrene resin, more specifically, a positive type resist that contains a resin having a repeating unit represented by any of the following Formulae (R-1) and (R-2) is exemplified.

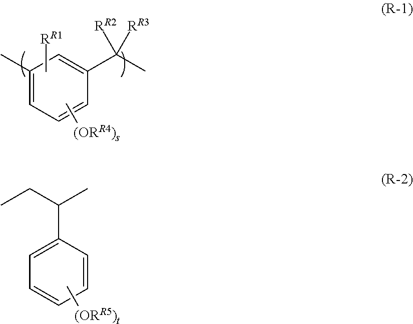

In the formulae, R^{R1} to R^{R5} each independently represent a hydrogen atom or an alkyl group (the number of carbon atoms is preferably in a range of 1 to 12, more preferably in a range of 1 to 6, and particularly preferably in a range of 1 to 3). s represents an integer of 1 to 3. t represents an integer of 1 to 5. The molecular weight of the resin is not particularly limited, but the weight average molecular weight thereof is typically in a range of 1000 to 1000000, preferably in a range of 2000 to 100000, and more preferably in a range of 3000 to 50000 in terms of polystyrene.

The resist may be exposed according to a usual method, but can be performed by irradiating the resist with active energy rays selected from a g-line, an h-line, an i-line, KrF excimer laser, and ArF excimer laser. It is preferable that the exposure is performed at an illuminance of 5000 W/m² to 18000 W/m⁻.

[Manufacture of Semiconductor-Substrate Product]

According to a method for manufacturing a semiconductor device according to the preferred embodiment of the present invention, first, a gate insulating film formed of high-dielectric constant materials (such as HfSiO4, ZiO2, ZiSiO4, Al2O3, HfO2, and La2O3) or a gate electrode layer formed of polysilicon is formed on a substrate (for example, an ion-implanted n-type or p-type substrate) using a technique of sputtering or the like (etched-layer formation process). Next, the formed gate insulating film or gate electrode layer is coated with a resist and a predetermined pattern is formed by photolithography. After the pattern is formed, an unnecessary portion of the resist is developed and removed (resist development process), the resist pattern is used as a mask and an unmasked region is subjected to dry etching or wet etching (etching process), and then the gate insulating film or gate electrode layer is removed. Thereafter, in an ion implantation treatment (ion implantation process), ionized p-type or n-type impurity elements are implanted into the substrate so that a p-type or n-type impurity implantation region (so-called source/drain region) is formed on the substrate. Subsequently, if necessary, a treatment of stripping the resist film remaining on the substrate is performed after an ashing treatment (ashing process) is performed.

In the present embodiment, a salicide process described below may be performed. Specifically, it is preferable that the semiconductor-substrate product having a desired structure is manufactured by performing a process of obtaining a semiconductor substrate in which a layer of a substrate and a metal layer are formed on a silicon wafer, a process of annealing the semiconductor substrate, and a process of applying a stripper to the semiconductor substrate to be treated. Moreover, the order of the processes is not limitatively interpreted and other processes may be further included between respective processes. The size of a wafer is not particularly limited, but a wafer whose diameter is 8 inches, 12 inches, or 14 inches is preferably used (1 inch=25.4 mm)

In the present invention, it is possible to realize suppression or prevention of damage to polysilicon when a modified resist is stripped off Examples of silicon materials generally include monocrystalline silicon, polycrystalline silicon (polysilicon), and amorphous silicon (noncrystalline silicon).

The monocrystalline silicon indicates silicon crystals in which the orientation of atomic arrangement is uniform throughout the whole crystals, but various defects are present when the crystals are practically observed at an atomic level.

The polycrystalline silicon indicates block or layered silicon formed of multiple single crystal grains whose orientations of crystals are different from each other. The polycrystalline silicon may include silicon formed with only Si or silicon doped with boron or phosphorus. In addition, silicon with various defects or impurities similar to that described above may be included within a range in which desired effects are exhibited. The production method is not particularly limited, and silicon formed by a CVD method is exemplified.

The polysilicon is occasionally applied to a gate electrode or the like in a semiconductor substrate. According to the preferred embodiment of the present invention, the modified resist can be desirably removed in a state in which a polysilicon-containing layer described above is exposed.

In the present specification, the modified resist indicates a resist in a state of being chemically or physically denatured due to the influence of asking or etching. Typically, as described above, a resist which is modified due to the plasma etching or dry etching is exemplified. The state of modification of a resist is not particularly limited, a case where a polymer compound constituting a resist is chemically changed and a molecular state having a different structure is formed is exemplified.

In addition, the term “preparation” in the present specification means that a specific material is included through synthesis or a mixture or a predetermined product is provided by purchase. Moreover, in the present specification, use of the stripper so as to treat respective materials of the semiconductor substrate is referred to as “application,” but the embodiment thereof is not particularly limited thereto. For example, the application broadly includes the stripper being brought into contact with the substrate. Specifically, the treatment may be performed by immersing a batch type device or performed through ejection using a sheet type device.

### EXAMPLES

Hereinafter, the present invention will be specifically described with reference to Examples, but the present invention is not limited to Examples described below. Further, “%” or “part” shown as the formulation or the blending amount in Examples is on a mass basis unless otherwise noted.

### Example 1 and Comparative Example 1

### Preparation of Test Substrate

A SiOₓ layer was formed on a commercially available silicon substrate (diameter: 12 inches). A polysilicon layer (thickness: 1000 Å) was formed on the SiOx layer according to a CVD method. Further, germanium was epitaxially grown on another silicon substrate and a layer having a thickness of 500 Å was formed. As a resist, a KrF resist “GKRS-6953A01G” [trade name, manufactured by Fujifilm Electronic Materials Co., Ltd.] (containing a hydroxystyrene resin) was used and this resist was formed on the substrate by a spin coater. The thickness of the resist at this time was 10 μm. In addition, an optional photomask was used and an exposure treatment was performed.

Next, As+ was ion-implanted into the above-described resist film. It was confirmed that the modified resist after ion implantation was cured. At this time, the dosage was greater than 1×10¹⁴ cm⁻².

(Test for Applying Stripper)

The treatment was performed under the following conditions in a sheet type device (POLOS (trade name), manufactured by SPS-Europe B. V.) with respect to the blanket wafer and the substrate for a test and an evaluation test was carried out.
Treatment temperature: 60°
Ejection amount: 1 L/min.
Wafer rotation speed: 500 rpm
Nozzle movement speed: 7 cm/s
Treatment time: polysilicon substrate and germanium substrate: 10 min resist substrate: 2 min

In addition, the stripper was supplied using a device of FIG. 2. The stripper was used for the test within 5 minutes after being prepared.

(Method for Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(pH)

The pH was measured at room temperature (25° C.) using F-51 (trade name, manufactured by HORIBA, Ltd.). The pH of a liquid chemical of Test No. 101 was 14.

(Etching Rate)

The etching rate (ER) of the germanium-containing layer was calculated by measuring the film thickness before or after the etching treatment using Ellipsometry (VASE Spectroscopic ellipsometer was used, J. A. Woollam, Japan). The average value of five points was adopted (measurement conditions measurement range: 1.2 eV to 2.5 eV, measuring angles: 70 degrees and 75 degrees).

The etching rate of the polysilicon layer was measured in the same manner.

(Release Properties)

The stripper in the tables was applied to the resist after plasma asking described above under the above-described conditions and the release properties of the resist were confirmed using an optical microscope (MX50, manufactured by Olympus Corporation). The results thereof are listed in the tables.

A: The resist was removed without a residue.

B: The residual resist amount was approximately ¼ compared to that before the treatment.

C: The residual resist amount was approximately ½ compared to that before the treatment.

D: No change was found compared to the treatment of the stripper.

TABLE 1-1

| | Blending | | | | | | | | | | | | | Test results | | |
|---|---|---|---|---|---|---|---|---|---|---|---|---|---|---|---|---|
| | | | | | | | | Component | | Component | | Wa- | Meth- | Release | | Ge |
| | Alcohol | | Amine | | Quaternary ammonium | | | 1 | | 2 | | ter | anol | prop- | poly-Si | ER |
| | | % by | | % by | hydroxide (% by mass) | | | | % by | | % by | % by | % by | erties | ER | (Å/ |
| No. | | mass | | mass | TBAH | TEAH | TMAH | | mass | | mass | mass | mass | of resist | (Å/min) | min) |
| 101 | Benzyl alcohol | 50.0 | MEA | 20.0 | 10.0 | | | | | | | 20.0 | | A | 5 | 10 |
| 102 | Benzyl alcohol | 50.0 | MEA | 20.0 | | 10.0 | | | | | | 20.0 | | A | 10 | 11 |
| 103 | Benzyl alcohol | 50.0 | MEA | 19.0 | 1.0 | 10.0 | | | | | | 20.0 | | A | 10 | 10 |
| 104 | Benzyl alcohol | 50.0 | MEA | 19.0 | 1.0 | | 10.0 | | | | | 20.0 | | A | 40 | 10 |
| 105 | Benzyl alcohol | 50.0 | MEA | 19.0 | | 1.0 | 10.0 | | | | | 20.0 | | A | 40 | 8 |
| 106 | Benzyl alcohol | 60.0 | MEA | 10.0 | 10.0 | | | | | | | 20.0 | | A | 5 | 8 |
| 107 | Benzyl alcohol | 40.0 | MEA | 30.0 | 10.0 | | | | | | | 20.0 | | A | 5 | 9 |
| 108 | Benzyl alcohol | 50.0 | MEA | 25.0 | 10.0 | | | | | | | 15.0 | | A | 5 | 10 |
| 109 | Benzyl alcohol | 50.0 | MEA | 34.0 | 6.0 | | | | | | | 10.0 | | A | 4 | 7 |
| 110 | Benzyl alcohol | 50.0 | MEA | 42.0 | 3.0 | | | | | | | 5.0 | | B | 0 | 6 |
| 111 | Benzyl alcohol | 50.0 | MEA | 44.0 | 2.0 | | | | | | | 4.0 | | C | 0 | 5 |
| 112 | Benzyl alcohol | 50.0 | MEA | 20.0 | 10.0 | | | DEHA | 0.3 | PEI | 0.5 | 19.2 | | A | 5 | 5 |
| 113 | Benzyl alcohol | 50.0 | MEA | 20.0 | | 10.0 | | DEHA | 0.3 | PEI | 0.5 | 19.2 | | A | 10 | 6 |
| 114 | Benzyl alcohol | 50.0 | MEA | 19.0 | 1.0 | 10.0 | | DEHA | 0.3 | PEI | 0.5 | 19.2 | | A | 10 | 5 |
| 115 | Benzyl alcohol | 50.0 | MEA | 19.0 | 1.0 | | 10.0 | DEHA | 0.3 | PEI | 0.5 | 19.2 | | A | 40 | 5 |
| 116 | Benzyl alcohol | 50.0 | MEA | 19.0 | | 1.0 | 10.0 | DEHA | 0.3 | PEI | 0.5 | 19.2 | | A | 40 | 3 |
| 117 | Benzyl alcohol | 60.0 | MEA | 10.0 | 10.0 | | | DEHA | 0.3 | PEI | 0.5 | 19.2 | | A | 5 | 3 |
| 118 | Benzyl alcohol | 40.0 | MEA | 30.0 | 10.0 | | | DEHA | 0.3 | PEI | 0.5 | 19.2 | | A | 5 | 4 |
| 119 | Benzyl alcohol | 50.0 | MEA | 25.0 | 10.0 | | | DEHA | 0.3 | PEI | 0.5 | 14.2 | | A | 5 | 5 |
| 120 | Benzyl alcohol | 50.0 | MEA | 34.0 | 6.0 | | | DEHA | 0.3 | PEI | 0.5 | 9.2 | | A | 4 | 2 |

TABLE 1-2

| | Blending | | | | | | | | |
|---|---|---|---|---|---|---|---|---|---|
| | Alcohol | | Amine | | Quaternary ammonium | | | Component 1 | |
| | | % by | | % by | hydroxide (% by mass) | | | | % by |
| No. | | mass | | mass | TBAH | TEAH | TMAH | | mass |
| 121 | Benzyl alcohol | 50.0 | MEA | 42.0 | 3.0 | | | DEHA | 0.3 |
| 122 | Benzyl alcohol | 50.0 | MEA | 44.0 | 2.0 | | | DEHA | 0.3 |
| 123 | Benzyl alcohol | 50.0 | AEE | 20.0 | 10.0 | | | DEHA | 0.3 |
| 124 | Benzyl alcohol | 50.0 | DEA | 20.0 | 10.0 | | | DEHA | 0.3 |
| 125 | 2-methyl-2,4-pentanediol | 50.0 | MEA | 20.0 | 10.0 | | | | |
| 126 | 2-methyl-2,4-pentanediol | 50.0 | MEA | 20.0 | | 10.0 | | | |
| 127 | 2-methyl-2,4-pentanediol | 50.0 | MEA | 19.0 | 1.0 | 10.0 | | | |
| 128 | 2-methyl-2,4-pentanediol | 50.0 | MEA | 19.0 | 1.0 | | 10.0 | | |
| 129 | 2-methyl-2,4-pentanediol | 50.0 | MEA | 19.0 | | 1.0 | 10.0 | | |
| 130 | 2-methyl-2,4-pentanediol | 60.0 | MEA | 10.0 | 10.0 | | | | |
| 131 | 2-methyl-2,4-pentanediol | 40.0 | MEA | 30.0 | 10.0 | | | | |
| 132 | 2-methyl-2,4-pentanediol | 50.0 | MEA | 25.0 | 10.0 | | | | |
| 133 | 2-methyl-2,4-pentanediol | 50.0 | MEA | 34.0 | 6.0 | | | | |
| 134 | 2-methyl-2,4-pentanediol | 50.0 | MEA | 42.0 | 3.0 | | | | |
| 135 | 2-methyl-2,4-pentanediol | 50.0 | MEA | 44.0 | 2.0 | | | | |
| 136 | 2-methyl-2,4-pentanediol | 52.0 | MEA | 44.0 | 2.0 | | | | |
| 137 | 2-methyl-2,4-pentanediol | 53.0 | MEA | 44.0 | 2.0 | | | | |
| 138 | 2-methyl-2,4-pcntancdiol | 50.0 | MEA | 20.0 | 10.0 | | | DEHA | 0.3 |
| 139 | 2-methyl-2,4-pentanediol | 50.0 | MEA | 20.0 | | 10.0 | | DEHA | 0.3 |
| 140 | 2-methyl-2,4-pentanediol | 50.0 | MEA | 19.0 | 1.0 | 10.0 | | DEHA | 0.3 |

| | Blending | | | | Test results | | |
|---|---|---|---|---|---|---|---|
| | Component 2 | | Water | Methanol | Release | | |
| | | % by | % by | % by | properties | poly-Si ER | Ge ER |
| No. | | mass | mass | mass | of resist | (Å/min) | (Å/min) |
| 121 | PEI | 0.5 | 4.2 | | B | 0 | 1 |
| 122 | PEI | 0.5 | 3.2 | | C | 0 | 0 |
| 123 | PEI | 0.5 | 19.2 | | A | 5 | 5 |
| 124 | PEI | 0.5 | 19.2 | | A | 5 | 5 |
| 125 | | | 20.0 | | A | 5 | 10 |
| 126 | | | 20.0 | | A | 10 | 11 |
| 127 | | | 20.0 | | A | 10 | 10 |
| 128 | | | 20.0 | | A | 30 | 10 |
| 129 | | | 20.0 | | A | 30 | 8 |
| 130 | | | 20.0 | | A | 5 | 8 |
| 131 | | | 20.0 | | A | 5 | 9 |
| 132 | | | 15.0 | | A | 5 | 10 |
| 133 | | | 10.0 | | A | 4 | 7 |
| 134 | | | 5.0 | | B | 0 | 6 |
| 135 | | | 4.0 | | B | 0 | 5 |
| 136 | | | 2.0 | | C | 0 | 5 |
| 137 | | | 1.0 | | C | 0 | 5 |
| 138 | PEI | 0.5 | 19.2 | | A | 5 | 5 |
| 139 | PEI | 0.5 | 19.2 | | A | 10 | 6 |
| 140 | PEI | 0.5 | 19.2 | | A | 5 | 5 |

TABLE 1-3

| | Blending | | | | | | | | |
|---|---|---|---|---|---|---|---|---|---|
| | Alcohol | | Amine | | Quaternary ammonium | | | Component 1 | |
| | | % by | | % by | hydroxide (% by mass) | | | | % by |
| No. | | mass | | mass | TBAH | TEAH | TMAH | | mass |
| 141 | 2-methyl-2,4-pentanediol | 50.0 | MEA | 19.0 | 1.0 | | 10.0 | DEHA | 0.3 |
| 142 | 2-methyl-2,4-pentanediol | 50.0 | MEA | 19.0 | | 1.0 | 10.0 | DEHA | 0.3 |
| 143 | 2-methyl-2,4-pentanediol | 60.0 | MEA | 10.0 | 10.0 | | | DEHA | 0.3 |
| 144 | 2-methyl-2,4-pentanediol | 40.0 | MEA | 30.0 | 10.0 | | | DEHA | 0.3 |
| 145 | 2-methyl-2,4-pentanediol | 50.0 | MEA | 25.0 | 10.0 | | | DEHA | 0.3 |
| 146 | 2-methyl-2,4-pentanediol | 50.0 | MEA | 34.0 | 6.0 | | | DEHA | 0.3 |
| 147 | 2-methyl-2,4-pentanediol | 50.0 | MEA | 42.0 | 3.0 | | | DEHA | 0.3 |
| 148 | 2-methyl-2,4-pentanediol | 50.0 | MEA | 44.0 | 2.0 | | | DEHA | 0.3 |
| 149 | 2-methyl-2,4-pentanediol | 52.0 | MEA | 44.0 | 2.0 | | | DEHA | 0.3 |
| 150 | 2-methyl-2,4-pentanediol | 50.0 | AEE | 20.0 | 10.0 | | | DEHA | 0.3 |
| 151 | 2-methyl-2,4-pentanediol | 50.0 | DEA | 20.0 | 10.0 | | | DEHA | 0.3 |
| 152 | 2-phenylethanol | 50.0 | MEA | 20.0 | 10.0 | | | DEHA | 0.3 |
| 153 | 2-phenoxyethanol | 50.0 | MEA | 20.0 | 10.0 | | | DEHA | 0.3 |
| 154 | 3-methoxy-3-methyl- | 50.0 | MEA | 20.0 | 10.0 | | | DEHA | 0.3 |
| | 1-butanol | | | | | | | | |
| 155 | 2-ethylhexanol | 50.0 | MEA | 20.0 | 10.0 | | | DEHA | 0.3 |
| 156 | Cyclohexanol | 50.0 | MEA | 20.0 | 10.0 | | | DEHA | 0.3 |
| 157 | Ethylene glycol | 50.0 | MEA | 20.0 | 10.0 | | | DEHA | 0.3 |
| 158 | Propylene glycol | 50.0 | MEA | 20.0 | 10.0 | | | DEHA | 0.3 |
| 201 | | | | | | | 10.0 | | |
| 202 | | | | | | | 10.0 | DMSO | 70.0 |
| 203 | | | MEA | 70.0 | | | 10.0 | | |
| 204 | Bcnzyl alcohol | 42.0 | MEA | 42.0 | | | 4.0 | | |
| 205 | | | | | | | | Sulfuric | 75.0 |
| | | | | | | | | acid | |
| 206 | | | | | 4.0 | | | DMSO | 96.0 |
| 207 | | | | | | | 4.0 | DMSO | 84.0 |
| 208 | | | MEA | 84.0 | | | 4.0 | | |

| | Blending | | | | Test results | | |
|---|---|---|---|---|---|---|---|
| | Component 2 | | Water | Methanol | Release | | |
| | | % by | % by | % by | properties | poly-Si ER | Ge ER |
| No. | | mass | mass | mass | of resist | (Å/min) | (Å/min) |
| 141 | PEI | 0.5 | 19.2 | | A | 30 | 5 |
| 142 | PEI | 0.5 | 19.2 | | A | 30 | 3 |
| 143 | PET | 0.5 | 19.2 | | A | 5 | 3 |
| 144 | PEI | 0.5 | 19.2 | | A | 5 | 4 |
| 145 | PEI | 0.5 | 14.2 | | A | 5 | 5 |
| 146 | PEI | 0.5 | 9.2 | | A | 4 | 2 |
| 147 | PEI | 0.5 | 4.2 | | B | 0 | 1 |
| 148 | PEI | 0.5 | 3.2 | | C | 0 | 0 |
| 149 | PEI | 0.5 | 1.2 | | C | 0 | 0 |
| 150 | PEI | 0.5 | 19.2 | | A | 5 | 5 |
| 151 | PEI | 0.5 | 19.2 | | A | 5 | 5 |
| 152 | PEI | 0.5 | 19.2 | | A | 5 | 5 |
| 153 | PEI | 0.5 | 19.2 | | A | 5 | 5 |
| 154 | PEI | 0.5 | 19.2 | | B | 5 | 5 |
| 155 | PEI | 0.5 | 19.2 | | B | 5 | 5 |
| 156 | PEI | 0.5 | 19.2 | | B | 5 | 5 |
| 157 | PEI | 0.5 | 19.2 | | B | 5 | 5 |
| 158 | PEI | 0.5 | 19.2 | | B | 5 | 5 |
| 201 | | | 90.0 | | B | >200 | >100 |
| 202 | | | 20.0 | | C | >200 | 70 |
| 203 | | | 20.0 | | C | >200 | 60 |
| 204 | | | | 12.0 | D | 0 | 50 |
| 205 | H₂O₂ | 7.5 | 17.5 | | A | 0 | >100 |
| 206 | | | | | C | 100 | >100 |
| 207 | | | | 12.0 | D | 0 | >100 |
| 208 | | | | 12.0 | D | 0 | >100 |

<Annotation of Table>

TMAH: tetramethyl ammonium hydroxide

TEAH: tetraethyl ammonium hydroxide

TBAH: tetrabutyl ammonium hydroxide

MEA: 2-aminoethanol

AEE: 2-(2-aminoethoxy)ethanol

DEA: diethanolamine

DEHA: N,N-diethylhydroxylamine

PEI: polyethyleneimine (weight average molecular weight: 2000)

DMSO: dimethyl sulfoxide

ER: etching rate

1 Å=0.1 nm

The liquid chemicals in the tests 206 to 208 correspond to those in Examples S-008, S-009, and S-035 of JP2013-500503A.

From the results described above, according to the stripper of the present invention, it was understood that organic materials present on the semiconductor substrate having a layer that includes germanium can be desirably treated.

### Example 2

0.1% by mass of N-2-(aminoethyl)-3 aminopropylmethyldimethoxysilane (KBM-602, manufactured by Shin-Etsu Chemical Co., Ltd.) and N-2-(aminoethyl)-3-aminopropyltrimethoxysilane (ICBM-603, manufactured by Shin-Etsu Chemical Co., Ltd.) were respectively added (the composition was adjusted by reducing the amount of water) to the strippers of Examples 112 to 124 and 138 to 158. When the stripping test of a resist was performed using the strippers, the release properties of the resist was not changed and the etching rate (ER) of the polysilicon (poly-Si) was decreased by half. From the results, it was understood that a silicon compound is effective for protection of polysilicon.

### Example 3

0.5% by mass of each of the above-described exemplary compounds A-2 to A-18, B-1 to B-27 was added to the liquid chemical of Test No. 101. As a result, it was confirmed that the anticorrosion properties of germanium (Ge) were improved in all cases.

Strippers were respectively prepared using 1,4-butanediol and hexylene glycol(2-methylpentane-2,4-diol) in place of 2-methyl-2,4-pentanediol of Test No. 101 described above. In both strippers, it was confirmed that excellent release properties with respect to the modified resist and excellent protection properties with respect to polysilicon and germanium were exhibited.

Strippers were respectively prepared using N-methylethanolamine (NMEA), N,N-dimethyl ethanol amine (DMMEA), N-methyldiethanolamine (DEMEA), aminoethylethanolamine (AEMEA), N,N-dimethylaminoethylethanolamine (DMAEMEA), N,N-dimethylaminoethoxyethanol (DMAEE), and propanolamine (MPA) in place of monoethanolamine(2-aminoethanol) (MEA) of Test No. 101 described above. In both strippers, it was confirmed that excellent release properties with respect to the modified resist and excellent protection properties with respect to polysilicon and germanium were exhibited.

The present invention has been described with reference to the embodiments, but the detailed description of the invention is not intended to limit the invention unless otherwise noted and the present invention should be broadly interpreted without departing from the spirit and the scope described in the aspects of the invention.

The present application claims priority based on Japanese Patent Application No. 2013-238343 filed in Japan on Nov. 18, 2013 and Japanese Patent Application No. 2013-259532 filed in Japan on Dec. 16, 2013 and the contents of which are incorporated herein by reference.

### EXPLANATION OF REFERENCES

1: silicon substrate
2, 3: well
21: source base portion
22: source silicide portion
23: drain base portion
24: drain silicide portion
4: gate insulating film
5: gate electrode
6: interlayer insulator
7: resist layer
71: modified-resist layer
72: unmodified-resist layer
73: plasma-modified resist layer
74: plasma-unmodified resist layer
11: treatment container (treatment tank)
12: rotary table
13: ejection opening
A: introduction port
S: substrate

What is claimed is:

1. A stripping method comprising:
applying an etching solution to a semiconductor substrate to strip a modified resist on the semiconductor substrate,
wherein the etching solution contains an alcohol compound and a quaternary ammonium hydroxide compound, and
the quaternary ammonium hydroxide compound is at least one of tetraethylammonium hydroxide and tetrabutylammonium hydroxide.

2. The stripping method according to claim 1, wherein the semiconductor substrate has a germanium-containing layer or a polysilicon-containing layer.

3. The stripping method according to claim 1 which is applied to the semiconductor substrate in a temperature range of 30° C. to 80° C.

4. The stripping method according to claim 2, wherein the etching rate of germanium or polysilicon is 200 Å/min or less.

5. The stripping method according to claim 1, wherein the alcohol compound is a compound represented by the following Formula (O-1) or (O-2),
R^{O1}—(—O—R^{O2}—)ₙ—OH (O-1)
R^{O1} represents a hydrogen atom, an alkyl group having 1 to 12 carbon atoms, or an aryl group having 6 to 14 carbon atoms, R^{O2} represents a linear or branched alkylene chain having 1 to 12 carbon atoms, n represents an integer of 0 to 6, and when n represents 2 or greater, a plurality of R^{O2}'s may be different from each other, and in this case, when n represents 0, R^{O1} does not represent a hydrogen atom,
R^{O3}-L^{O1}-R^{O4}—OH (O-2)
R^{O3} represents a cyclic structural group which may have a substituent, L^{O1} represents a single bond, O, CO, NR^{N}, S, or a combination of these, R^{O4} represents a single bond, an alkylene group, an arylene group, or an aralkylene group, R^{N} represents a hydrogen atom, an alkyl group having 1 to 12 carbon atoms, an alkenyl group having 2 to 12 carbon atoms, or an aryl group having 6 to 14 carbon atoms, and when L^{O1} represents a linking group other than a single bond, le does not represent a single bond.

6. The stripping method according to claim 1, wherein a C Log P value of the alcohol compound is 0 or greater.

7. The stripping method according to claim 1, wherein the alcohol compound is selected from 2-methyl-2,4-pentanediol, 3-methoxy-3-methyl-1-butanol, ethylene glycol, propylene glycol, benzyl alcohol, 2-phenylethanol, 2-phenoxyethanol, 2-ethylhexanol, and cyclohexanol.

8. The stripping method according to claim 1, wherein the etching solution contains 10% by mass to 80% by mass of the alcohol compound.

9. The stripping method according to claim 1, wherein the etching solution contains 20% by mass or less of the quaternary ammonium hydroxide compound.

10. The stripping method according to claim 1, wherein the etching solution further contains 1% by mass to 50% by mass of water.

11. The stripping method according to claim 1, wherein the etching solution further contains 1% by mass to 60% by mass of an organic amine compound.

12. The stripping method according to claim 2, wherein the etching solution includes an anticorrosive component of the germanium-containing layer.

13. The stripping method according to claim 12, wherein the anticorrosive component of the germanium-containing layer is formed of a compound represented by any of the following Formulae (1) to (6), (10), and (11) or a compound having a repeating unit represented by any of the following Formulae (7) to (9), 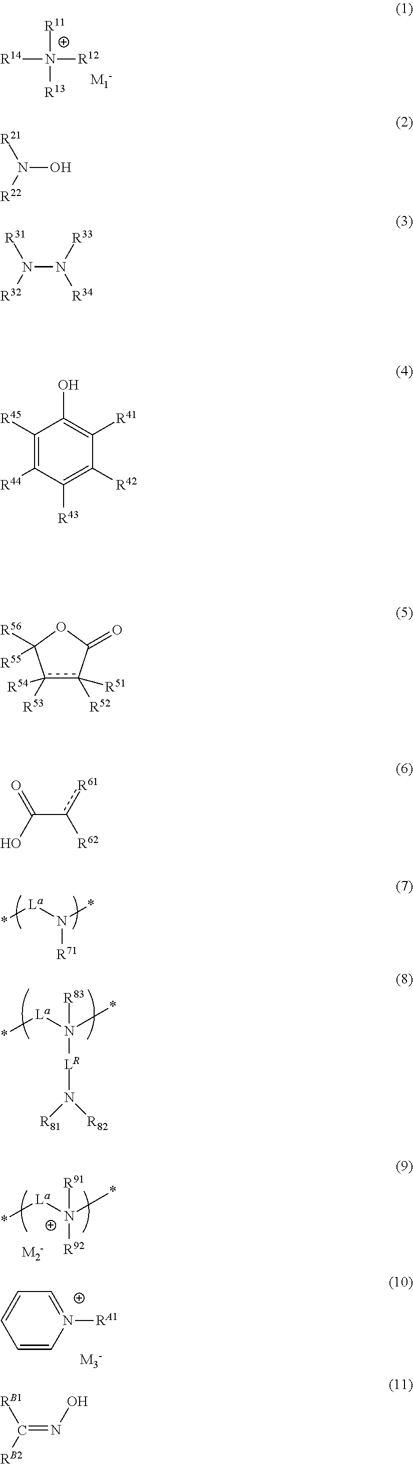
R¹¹ to R¹⁴, R²¹, R²², R³¹ to R³⁴, R⁴¹ to R⁴⁵, R⁵¹ to R⁵⁶, R⁶¹, R⁶², R⁷¹, R⁸¹ to R⁸³, R⁹¹, R⁹², R^{A1}, R^{B1}, and R^{B2} each independently represent a group including a hydrogen atom, a carbon atom, an oxygen atom, a sulfur atom, or a nitrogen atom, L^{a} represents a linking group, M₁⁻, M₂⁻, and M₃⁻ represent a counter anion, the broken line in Formula (5) represents any of a single bond and a double bond, and in the case where the broken line represents a double bond, R⁵² and R⁵⁴ are not present, the broken line in Formula (6) means that R⁶¹ represents an oxygen atom or a sulfur atom so that the oxygen atom or the sulfur atom may constitute a carbonyl group or a thiocarbonyl group together with a carbon atom to which the oxygen atom or the sulfur atom is bonded, and L^{R} represents a single bond or a linking group.

14. The stripping method according to claim 2, wherein the etching solution includes a silicon compound as an anticorrosive component of the polysilicon-containing layer.

15. A method for manufacturing a semiconductor-substrate product comprising:
manufacturing a semiconductor-substrate product by performing processes of the stripping method according to claim 1.

16. A stripper which removes a modified resist from a semiconductor substrate, comprising:
an alcohol compound; and
a quaternary ammonium hydroxide compound,
wherein the quaternary ammonium hydroxide compound is at least one of tetraethylammonium hydroxide and tetrabutylammonium hydroxide.

17. The stripper according to claim 16, wherein the semiconductor substrate has a germanium-containing layer or a polysilicon-containing layer.

18. The stripper according to claim 16, containing 10% by mass to 80% by mass of the alcohol compound.

19. The stripper according to claim 16, containing 20% by mass or less of the quaternary ammonium hydroxide compound.

20. The stripper according to claim 16, further containing 1% by mass to 50% by mass of water.

21. The stripper according to claim 16, further containing 1% by mass to 60% by mass of an organic amine compound.

22. The stripper according to claim 16, further containing 0.01% by mass to 30% by mass of a silicon compound.
